(19) United States
(12) Patent Application Publication
(10) Pub. No.: US 2016/0149135 A1
(43) Pub. Date: May 26, 2016

(54) VAPOR DEPOSITION PARTICLE PROJECTION DEVICE AND VAPOR DEPOSITION DEVICE

(71) Applicant: Sharp Kabushiki Kaisha, Osaka (JP)

(72) Inventors: Tohru SONODA, Osaka (JP); Shinichi KAWATO, Osaka (JP); Satoshi INOUE, Osaka (JP); Satoshi HASHIMOTO, Osaka (JP)

(21) Appl. No.: 15/011,398

(22) Filed: Jan. 29, 2016

Related U.S. Application Data
(63) Continuation of application No. 14/004,151, filed on Sep. 9, 2013.

(30) Foreign Application Priority Data
Mar. 11, 2011 (JP) 2011-054808

(51) Int. Cl. H01L 51/00; H01L 51/56

(52) U.S. Cl. CPC H01L 51/0011; H01L 51/001; H01L 51/56

(57) ABSTRACT

The vapor deposition particle injecting device (20) includes a crucible (22), a holder (21) having at least one injection hole (21a), and plate members (23 through 25) provided in the holder (21). The plate members (23 through 25) have respective openings (23a through 25a) corresponding to the injection hole (21a), and the plate members (23 through 25) are arranged away from each other in a direction perpendicular to the opening planes of the openings. The injection hole (21a) and the openings (23a through 25a) overlap each other in the plan view.

### TECHNICAL FIELD

The present invention relates to a vapor deposition particle injecting device and a vapor deposition device including the vapor deposition particle injecting device as a vapor deposition source.

### BACKGROUND ART

Recent years have witnessed practical use of a flat-panel display in various products and fields. This has led to a demand for a flat-panel display that is larger in size, achieves higher image quality, and consumes less power.

Under such circumstances, great attention has been drawn to an organic EL display device that (i) includes an organic electroluminescence (hereinafter abbreviated to “EL”) element which uses EL of an organic material and that (ii) is an all-solid-state flat-panel display which is excellent in, for example, low-voltage driving, high-speed response, and self-emitting.

An organic EL display device includes, for example, (i) a substrate made up of members such as a glass substrate and TFTs (thin film transistors) provided to the glass substrate and (ii) organic EL elements provided on the substrate and connected to the TFTs.

An organic EL element is a light-emitting element capable of high-luminance light emission based on low-voltage direct-current driving, and includes in its structure a first electrode, an organic EL layer, and a second electrode stacked on top of one another in that order, the first electrode being connected to a TFT.

The organic EL layer between the first electrode and the second electrode is an organic layer including a stack of layers such as a hole injection layer, a hole transfer layer, an electron blocking layer, a luminescent layer, a hole blocking layer, an electron transfer layer, and an electron injection layer.

A full-color organic EL display device typically includes organic EL elements of red (R), green (G), and blue (B) as sub-pixels aligned on a substrate. The full-color organic EL display device carries out an image display by, with use of TFTs, selectively causing the organic EL elements to each emit light with a desired luminance.

Organic EL elements in a light-emitting section of such an organic EL display device are generally formed by stacking organic films through vapor deposition. Such an organic EL display device is produced through a process that forms, for each organic EL element serving as a light-emitting element, a predetermined pattern of a luminescent layer made of an organic luminescent material which emits light of at least the above three colors.

Such formation of a predetermined pattern by stacking using vapor deposition is performed by a method such as a vapor deposition method using a mask referred to as a shadow mask, an inkjet method, or a laser transfer method. Currently, of these methods, a vacuum vapor deposition method using a mask referred to as a shadow mask is most commonly used.

According to the vacuum vapor deposition method using a mask referred to as a shadow mask, a vapor deposition source, which evaporates or sublimates a vapor deposition material, is placed inside a vacuum chamber whose inside can be kept at a reduced-pressure state, and, for example, the vapor deposition material is evaporated or sublimated by heating the vapor deposition material under a high vacuum.

Such a vacuum vapor deposition method uses, as a vapor deposition source, a vapor deposition particle injecting device which includes a heating container, referred to as a crucible, in which a vapor deposition material is contained.

FIG. 17 is a cross-sectional view schematically illustrating a configuration of a vapor deposition material injecting device 400 generally used in the vacuum vapor deposition method, together with a film formation substrate 200 and a vapor deposition mask 300. FIG. 18 is a perspective view schematically illustrating the vapor deposition particle injecting device 400 illustrated in FIG. 17.

As illustrated in FIG. 17 and FIG. 18, a vapor deposition material is heated in a crucible 402 so as to be evaporated or sublimated, and the vapor deposition material thus evaporated or sublimated is injected, as vapor deposition particles, to an outside from an injection hole 401a provided in a holder 401 containing the crucible 402.

The vapor deposition particles thus injected are deposited and stacked on the film formation substrate 200 through openings 301 of the vapor deposition mask 300 that has the openings 301 only in desired regions, as illustrated in FIG. 17. A vapor-deposited film can be thus formed on desired regions of the film formation substrate 200.

### CITATION LIST

### Patent Literature

[Patent Literature 1]

Japanese Patent Application Publication Tokukai No. 2004-137583 A (Publication date: May 13, 2004)

[Patent Literature 2]

Japanese Patent Application Publication Tokukai No. 2007-100216 A (Publication date: Apr. 19, 2007)

[Patent Literature 3]

Japanese Patent Application Publication Tokukai No. 2010-13731 A (Publication date: Jan. 21, 2010)

### SUMMARY OF INVENTION

### Technical Problem

However, as illustrated in FIG. 17, before the vapor deposition material evaporated or sublimated by being heated in the crucible 402 is injected as vapor deposition particles from the injection hole 401a, the vapor deposition particles are scattered by inner walls 401b of the holder 401 and repeatedly collide with one another.

Moreover, since the injection hole 401a of the vapor deposition particle injecting device 400 has a nozzle shape (tubular shape), the vapor deposition particles are scattered also by an inner wall of the injection hole 401a. Furthermore, since density of the vapor deposition particles increases in a narrow tubular part of the injection hole 401a, the vapor deposition particles collide with one another so as to be scattered.

As a result of such scattering of the vapor deposition particles, the vapor deposition particles injected from the injection hole 401a are injected in various directions. This causes a decline in directivity of the vapor deposition particles.

As described above, according to the conventional art, vapor deposition particles are reflected and scattered by the inner walls 401b of the holder 401 and by a wall surface of the injection hole 401a and are scattered in the vicinity of the injection hole 401a in which density of the vapor deposition particles is high. This causes an increase in proportion of vapor deposition particles to be injected in an oblique direction, thereby causing an increase in injection angle of the vapor deposition particles. That is, injected vapor deposition particles spread in a wide range.

In general, a distribution σ(θ) of a vapor deposition density of vapor deposition particles, in other words, a film thickness distribution of a vapor-deposited film deposited on the film formation substrate 200 is in accordance with a cosine law, and is empirically believed to be expressed by the following formula (1):

σ(θ)=A cosⁿ⁺³θ (1)

where θ is an angle formed by injected vapor deposition particles and a normal direction (see FIG. 18).

FIG. 19 is a vapor deposition particle distribution graph showing a relationship among (i) a distribution of a vapor deposition density of vapor deposition particles (vapor deposition particle distribution σ) which distribution is obtained by normalization with respect to a central film thickness (100% (σ=1.0)) of a vapor-deposited layer at θ=0, (ii) an injection angle θ of vapor deposition particles, and (iii) a coefficient n.

Conditions for measurement were as follows. A vapor deposition particle injecting device 400 having an injection hole 401a whose diameter is 2 mm and whose length in the normal direction is 25 mm was used as a vapor deposition source. A non-alkali glass substrate was used as the film formation substrate 200, Alq₃ (aluminum quinolinol complex, aluminato-tris-8-hydroxyquinolate, sublimate temperature: 305° C.) was used as a vapor deposition material. A distance between the non-alkali glass substrate and the injection hole 401a was 125 mm, a film formation rate was 0.1 nm/sec, and a degree of vacuum in a vacuum chamber was 1×10⁻³ Pa or less. Moreover, the film formation was carried out so that a film formed on the non-alkali glass substrate had a central film thickness of 100 nm. The temperature of the crucible 402 was 340° C. The height of the holder 401 was 80 mm.

As illustrated in FIG. 19, the distribution of the vapor deposition particles is more concentrated in a front direction (normal direction) of the injection hole 401a and directivity becomes higher as the value of n in the formula (1) becomes larger. Meanwhile, the vapor deposition particles spread wider as the directivity becomes lower.

The density of the vapor deposition particles is highest at the front of the injection hole 401a, and gradually declines as the injection angle θ becomes larger.

Therefore, lower directivity results in a larger amount of vapor deposition particles attached to regions other than the film formation substrate 200.

In the case of the general crucible-type vapor deposition particle injecting device 400 illustrated in FIG. 17, n is approximately 2 to 3. Even by elongating the injection hole 401a, the directivity does not improve since the vapor deposition particles are scattered by the inner wall of the injection hole 401a.

In a case of employing a vacuum vapor deposition method, vapor deposition particles injected towards the film formation substrate 200 contribute to film formation, but the other vapor deposition particles do not contribute to film formation.

Therefore, in the case of employing a vacuum vapor deposition method, all the vapor-deposited films other than the vapor-deposited film deposited on the film formation substrate 200 are a material loss. Accordingly, material utilization efficiency becomes lower as the directivity becomes lower.

The “material utilization efficiency” used herein refers to a ratio of an actually used amount of a vapor deposition material to a total use amount of the vapor deposition material, and is expressed by (an amount of the vapor deposition material attached to the film formation substrate 200 and to the vapor deposition mask 300)/(an amount of the vapor deposition material injected from the vapor deposition source).

An organic EL element in a light-emitting section of an organic EL display device is formed by stacking organic films through vapor deposition.

Especially, an organic material constituting an organic EL layer is a special functional material having properties such as an electrical conducting property, a carrier transport property, a light-emitting property, and thermal and electrical stability, and its cost is very expensive.

However, since the conventional vapor deposition particle injecting device 400 has low directivity as described above, a large amount of wasteful vapor deposition material is attached to regions other than the film formation substrate 200. This results in low material utilization efficiency.

It is therefore necessary to improve the material utilization efficiency.

One way to improve the material utilization efficiency is to increase directivity of the vapor deposition source so that vapor deposition particles are efficiently injected towards a region in which the film formation substrate 200 is provided.

Patent Literature 1 discloses controlling a direction of a vapor deposition flow by use of a regulating plate in order to make efficient use of an organic material of a vapor deposition source.

FIG. 20 is a cross-sectional view schematically illustrating (i) a film formation substrate 200 and (ii) a configuration of main parts of a vapor deposition particle injecting device 500 disclosed in Patent Literature 1.

The vapor deposition particle injecting device 500 illustrated in FIG. 20 includes three frames 501 to 503 that are stacked on each other. Around the frames 501 to 503, a coil 504 for heating is wound.

As illustrated in FIG. 20, the frame 501 provided in a lowermost layer contains a vapor deposition material, and serves as a heating section in which the vapor deposition material is heated to evaporate. The frame 501 contains the vapor deposition material and a filler 505 which generates heat by electromagnetic induction.

The frames 502 and 503 are each a vapor deposition flow control section which controls a direction of a vapor deposition flow traveling from the frame 501, which is the heating section, towards the film formation substrate 200. The frames 502 and 503 are each divided into a plurality of flow blocks 507 by regulating plates 506 each of which is provided so as to stand in a direction pointing from the frame 501 to the film formation substrate 200.

The vapor deposition flow is thus regulated in a direction along side surfaces of the regulating plates 506 separating the plurality of flow blocks 507.

The regulating plates 506 or the frames 502 and 503 are made of a material which generates heat or is heated by electromagnetic induction.

According to Patent Literature 1, since the vapor deposition source has the above configuration, a direction of a vapor deposition flow of the vapor deposition material evaporated in the frame 501 is controlled by the frames 502 and 503. This allows only a vapor deposition flow that has passed through the frames 502 and 503 to be directed to the film formation substrate 200. Meanwhile, the vapor deposition material that has not passed through the frames 502 and 503 is collected into the frame 501 provided in the lowermost layer. It is therefore possible to make efficient use of the vapor deposition material.

The vapor deposition flow is regulated in a direction along the side surfaces of the plurality of flow blocks 507.

(a) through (e) of FIG. 21 are perspective views each illustrating an example of a shape of the flow blocks 507 formed by the regulating plates 506.

However, according to the vapor deposition particle injecting device 500 disclosed in Patent Literature 1, the regulating plates 506 also are heated as described above. This causes thermal energy from the regulating plates 506 to be given to vapor deposition particles (which gather to form the vapor deposition flow) that have reached the surfaces of the regulating plates 506, thereby scattering a direction in which the vapor deposition particles travel.

Further, according to the vapor deposition particle injecting device 500 disclosed in Patent Literature 1, the frames 502 and 503 are each divided into the plurality of flow blocks 507 by the regulating plates 506. This increases density of the vapor deposition particles in each of the flow blocks 507.

As a result, the vapor deposition particles collide with one another. This also scatters the direction in which the vapor deposition particles travel.

With the structure, it is difficult to obtain directivity sufficient to allow the vapor deposition flow to be directed to the film formation substrate 200.

That is, the above method does not solve the influence of scattering caused by inner walls of a vapor deposition source and the influence of scattering caused by an increase in density of vapor deposition particles.

The present invention was accomplished in view of the above problems, and an object of the present invention is to provide a vapor deposition particle injecting device and a vapor deposition device which allow an improvement in directivity of vapor deposition particles with a simple structure.

### Solution to Problem

In order to attain the object, the vapor deposition particle injecting device of the present invention includes: (1) a vapor deposition particle generating section for generating vapor deposition particles in a form of gas by heating up a vapor deposition material; (2) a holder having an injection hole through which the vapor deposition particles are injected outside, the number of the injection hole being at least one; and (3) a plurality of plate members provided so as to constitute respective of a plurality of stages in the holder, each of the plurality of plate members having a through hole whose number corresponds to the number of the injection hole, and the plurality of plate members being arranged between the vapor deposition particle generating section and the injection hole so as to be spaced from each other in a direction perpendicular to opening planes of the injection hole and of the through holes, and the injection hole and the through holes overlapping each other when viewed in the direction perpendicular to the opening planes of the injection hole and of the through holes.

According to the configuration, the vapor deposition particles can directly reach the injection hole from the vapor deposition particle generating section via an area in which the through holes overlap each other. A maximum injection angle of the vapor deposition particles, which are thus injected outside via the injection hole without making contact with anywhere in the holder, is restricted to a narrower angle, as compared to a case where vapor deposition particles are reflected and scattered by the inner wall of the holder and then injected outside via the injection hole.

According to the configuration, it is possible to increase a ratio of vapor deposition particles which are moved at a small injection angle towards the upper layer via the through holes. This allows an improvement in directivity.

According to the configuration, it is possible to increase an apparent through hole length (nozzle length) in the opening direction of the injection hole (i.e., a direction from the vapor deposition particle generating section to the film formation substrate).

Further, the vapor deposition particle injecting device does not have a narrow space like a pipe. Therefore, density of vapor deposition particles is not increased in the vicinity of the through holes, and it is therefore possible to reduce a frequency with which vapor deposition particles collide with each other.

According to the configuration, therefore, it is possible to suppress or prevent collision and scattering of vapor deposition particles and to improve collimation (parallel flow) property of vapor deposition flows by utilizing a nozzle length effect.

As such, according to the configuration, it is possible to improve directivity of vapor deposition particles with a simple structure.

By employing the vapor deposition particle injecting device, distribution of a vapor deposition flow (vapor deposition particles) becomes smaller than that of a conventional technique. Consequently, it is possible to reduce an amount of vapor deposition particles which are to be vapor deposited in an unintended area, and it is therefore possible to improve material utilization efficiency.

According to the configuration, the directivity is improved and the spread angle of vapor deposition particles can be made smaller, as compared with the conventional technique. Therefore, even in a case where a vapor deposition flow, which is identical in amount with that of the conventional technique, is injected, the density of vapor deposition particles becomes higher than that of the conventional technique, and accordingly a vapor deposition speed is improved.

The vapor deposition device of the present invention includes the vapor deposition particle injecting device as a vapor deposition source.

According to the vapor deposition device, therefore, it is possible to improve directivity of vapor deposition particles with a simple structure and to improve material utilization efficiency as above described.

Moreover, according to the configuration, the directivity is improved and the spread angle of vapor deposition particles can be made smaller, as compared with the conventional technique. Therefore, even in a case where a vapor deposition flow, which is identical in amount with that of the conventional technique, is injected, the density of vapor deposition particles becomes higher than that of the conventional technique, and accordingly a vapor deposition speed is improved.

### Advantageous Effects of Invention

As above described, the vapor deposition particle injecting device and the vapor deposition device of the present invention includes the plurality of plate members provided so as to constitute respective of a plurality of stages between (i) the injection hole and (ii) the vapor deposition particle generating section for generating the vapor deposition particles, in the holder having the at least one injection hole through which the vapor deposition particles are injected outside.

Each of the plurality of plate members has at least one through hole whose number corresponds to the number of the at least one injection hole, and the plurality of plate members are arranged so as to be spaced from each other in the direction perpendicular to the opening planes of the injection hole and of the through holes, and the injection hole and the through holes overlap each other when viewed in the direction perpendicular to the opening planes of the injection hole and of the through holes.

Therefore, the vapor deposition particles can directly reach the injection hole from the vapor deposition particle generating section via an area in which the through holes overlap each other. A maximum injection angle of the vapor deposition particles, which are thus injected outside via the injection hole without making contact with anywhere in the holder, is restricted to a narrower angle, as compared to a case where vapor deposition particles are reflected and scattered by the inner wall of the holder and then injected outside via the injection hole.

According to the configuration, it is possible to increase a ratio of vapor deposition particles which are moved at a small injection angle towards the upper layer via the through holes. This allows an improvement in directivity.

According to the vapor deposition particle injecting device and the vapor deposition device, it is possible to (i) increase an apparent through hole length (nozzle length) in the opening direction of the injection hole (i.e., the direction from the vapor deposition particle generating section to the film formation substrate) and (ii) reduce a frequency with which vapor deposition particles collide with each other.

Therefore, it is possible to improve the directivity of vapor deposition particles with a simple structure, and it is accordingly possible to improve the material utilization efficiency. Moreover, since the density of vapor deposition particles is increased, it is possible to improve the vapor deposition speed.

### BRIEF DESCRIPTION OF DRAWINGS

FIG. 1 is a cross-sectional view schematically illustrating a configuration of a vapor deposition particle injecting device in accordance with Embodiment 1 of the present invention.

FIG. 2 is a cross-sectional view schematically illustrating main constituent elements in a vacuum chamber of a vapor deposition device, in accordance with Embodiment 1 of the present invention.

FIG. 3 is a cross-sectional view (i) for explaining how to determine a location of an inner wall of a holder in a space layer other than an uppermost layer and (ii) illustrating a main part of the vapor deposition particle injecting device in accordance with Embodiment 1 of the present invention.

(a) and (b) of FIG. 4 are a view schematically illustrating how a vapor-deposited film is formed with the use of two vapor deposition sources. (a) of FIG. 4 illustrates a case where the vapor deposition particle injecting device in accordance with Embodiment 1 of the present invention is used as the vapor deposition sources, and (b) of FIG. 4 illustrates a case where a general vapor deposition particle injecting device is used as the vapor deposition sources.

FIG. 5 is a graph illustrating a relation between a vapor deposition particle distribution and an injection angle of vapor deposition particles, in cases where the vapor deposition particle injecting device in accordance with Embodiment 1 of the present invention and a general vapor deposition particle injecting device are used as the vapor deposition sources.

FIG. 6 is a cross-sectional view schematically illustrating a configuration of an organic EL display device.

FIG. 7 is a cross-sectional view schematically illustrating a configuration of an organic EL element which constitutes a display section of an organic EL display device.

FIG. 8 is a flowchart illustrating, in a processing order, processes of manufacturing an organic EL display device.

(a) and (b) of FIG. 9 are a view schematically illustrating how a vapor-deposited film is formed with the use of one (1) vapor deposition source. (a) of FIG. 9 illustrates a case where the vapor deposition particle injecting device in accordance with Embodiment 1 of the present invention is used as the vapor deposition source, and (b) of FIG. 9 illustrates a case where a general vapor deposition particle injecting device is used as the vapor deposition source.

FIG. 10 is a cross-sectional view schematically illustrating a configuration in which a mesh-like auxiliary plate is provided in a holder in the vapor deposition particle injecting device in accordance with Embodiment 1 of the present invention.

FIG. 11 is a cross-sectional view schematically illustrating a configuration of a vapor deposition particle injecting device in accordance with Embodiment 2 of the present invention.

FIG. 12 is a cross-sectional view schematically illustrating a configuration of a vapor deposition particle injecting device in accordance with Embodiment 3 of the present invention.

(a) through (c) of FIG. 13 are a cross-sectional view illustrating modification examples of the vapor deposition particle injecting device of the present invention.

FIG. 14 is a cross-sectional view schematically illustrating a configuration of a main part of a vapor deposition device in accordance with Embodiment 4 of the present invention.

FIG. 15 is a perspective view schematically illustrating main constituent elements in a vacuum chamber of the vapor deposition device, in accordance with Embodiment 4 of the present invention.

FIG. 16 is a cross-sectional view schematically illustrating a configuration of the vapor deposition particle injecting device in accordance with Embodiment 4 of the present invention.

FIG. 17 is a cross-sectional view schematically illustrating a film formation substrate, a vapor deposition mask, and a configuration of a general vapor deposition material injecting device which is used in a vacuum vapor deposition method.

FIG. 18 is a perspective view schematically illustrating a configuration of the vapor deposition particle injecting device illustrated in FIG. 17.

FIG. 19 is a vapor deposition particle distribution graph illustrating a relation between a coefficient n, an injection angle of vapor deposition particles, and a vapor deposition particle distribution, which is indicative of a vapor deposition density distribution of vapor deposition particles, in a case where a central film thickness of a vapor-deposited film is normalized as 100% (σ=1.0) when θ=0.

FIG. 20 is a cross-sectional view schematically illustrating a film formation substrate and a configuration of main parts of a vapor deposition particle injecting device disclosed in Patent Literature 1.

(a) through (e) of FIG. 21 are a perspective view illustrating example shapes of flow blocks which are formed by the use of a regulating plate in Patent Literature 1.

### DESCRIPTION OF EMBODIMENTS

The following description will discuss embodiments of the present invention in detail.

### Embodiment 1

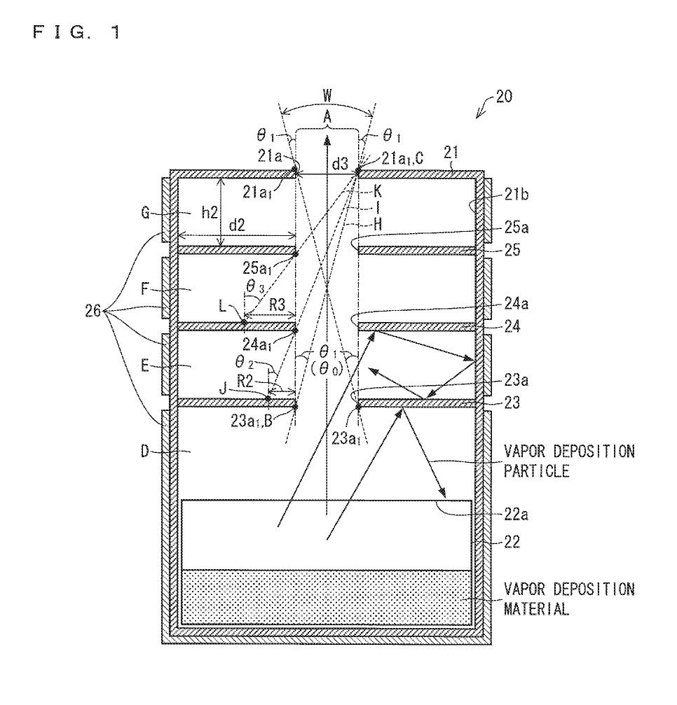

The following description will discuss an embodiment of the present invention with reference to FIGS. 1 through 10.

<Overall Configuration of Vapor Deposition Device>

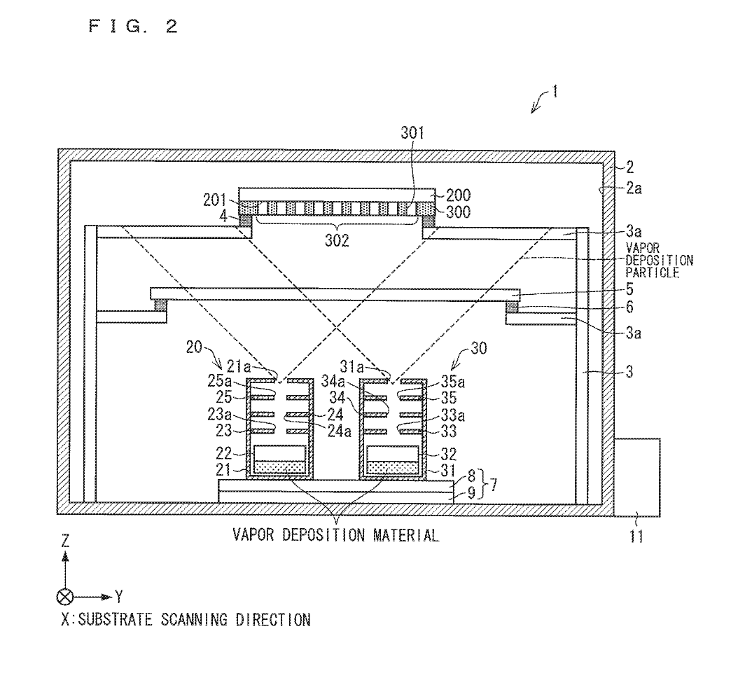

FIG. 2 is a cross-sectional view schematically illustrating main constituent elements in a vacuum chamber of a vapor deposition device in accordance with the present embodiment.

A vapor deposition device 1 of the present embodiment includes a vacuum chamber 2, a frame 3, a movable supporting unit 4, a shutter 5, a shutter operating unit 6, a vapor deposition particle injecting device moving unit 7, vapor deposition particle injecting devices 20 and 30, a control section (control circuit, not illustrated), and the like (see FIG. 2).

The frame 3, the movable supporting unit 4, the shutter 5, the shutter operating unit 6, the vapor deposition particle injecting device moving unit 7, and the vapor deposition particle injecting devices 20 and 30 are provided in the vacuum chamber 2. In the vacuum chamber 2, a vapor deposition mask 300 (vapor deposition mask, hereinafter referred to as “mask”) and a film formation substrate 200 are provided above the vapor deposition particle injecting devices 20 and 30 so that the mask 300 and the film formation substrate 200 face the vapor deposition particle injecting devices 20 and 30.

Note that the following description discusses an example in which the mask 300 (i) has a size corresponding to that of the film formation substrate 200 (e.g., has an identical size in a plan view) and (ii) is fixed in close contact with a film formation surface 201 of the film formation substrate 200 with a fixing means (not illustrated).

Note, however, that the present embodiment is not limited to the example. The mask 300 can be provided apart from the film formation substrate 200 and can have a size smaller than that of a film formation area of the film formation substrate 200, as later described in other embodiments.

Alternatively, in a case where a vapor-deposited film is formed in an all-over pattern on the film formation substrate 200, the mask 300 can be omitted.

As such, the mask 300 can be optionally provided, that is, the mask 300 can be either provided as one of constituent members of the vapor deposition device 1 as an attachment of the vapor deposition device 1 or not.

<Configuration of Mask 300>

The mask 300 has an opening 301 (through hole) which is provided in an intended location and has an intended shape, and only vapor deposition particles which have passed through the opening 301 of the mask 300 reach the film formation substrate 200 so as to form a vapor-deposited film.

In a case where vapor-deposited films are formed on the film formation substrate 200 for respective pixels, a fine mask, which has openings 301 for respective pixels, is employed as the mask 300.

Alternatively, in a case where a film is vapor deposited in an entire display area on the film formation substrate 200, an open mask is employed which has an opening that corresponds to the entire display area.

Examples of films formed for the respective pixels encompass a luminescent layer, and examples of a film formed in the entire display area encompass a hole transfer layer.

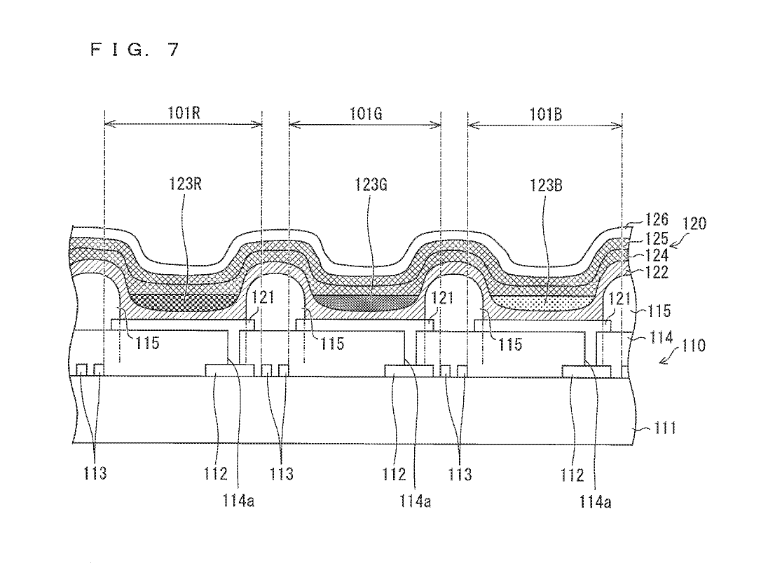

In a case where, for example, a pattern of vapor-deposited films is formed for selectively forming luminescent layers 123R, 123G, and 123B on a TFT (thin film transistor) substrate 110 (later described with reference to FIG. 7) as a film pattern formed on the film formation substrate 200, the openings 301 are formed in correspondence with the size and pitch of columns for each of colors of the luminescent layers 123R, 123G, and 123B.

Note that FIG. 2 illustrates an example case in which the mask 300 has a plurality of belt-like (striped) openings 301 which are arranged in a one-dimensional direction.

A longitudinal direction of the openings 301 is in parallel with a scanning direction (i.e., a substrate carrying direction, an X-axis direction in FIG. 2), and the plurality of openings 301 are arranged in a direction (i.e., a Y-axis direction in FIG. 2) perpendicular to the scanning direction.

For example, a metal mask can be suitably employed as the mask 300. Note, however, that the mask 300 is not limited to this.

<Configuration of Vacuum Chamber 2>

In the vacuum chamber 2, a vacuum pump 11 is provided for vacuum-pumping the vacuum chamber 2 via an exhaust port (not illustrated) of the vacuum chamber 2 to keep a vacuum in the vacuum chamber 2 during vapor deposition.

In a case where a degree of vacuum is higher than 1.0×10⁻³ Pa, a necessary and sufficient mean free path of vapor deposition particles can be obtained. On the other hand, in a case where the degree of vacuum is lower than 1.0×10⁻³ Pa, the mean free path becomes shorter, and therefore the vapor deposition particles are scattered. This causes (i) a decrease in efficiency of the vapor deposition particles to reach the film formation substrate 200 and (ii) a decrease of collimate components.

Under the circumstances, the vacuum chamber 2 is set to have a degree of vacuum of 1.0×10⁻⁴ Pa or more by the vacuum pump 11. In other words, a pressure in the vacuum chamber 2 is set to 1.0=10⁻⁴ Pa or lower.

<Configuration of Frame 3>

The frame 3 is provided adjacently to an inner wall 2a of the vacuum chamber 2 (see FIG. 2).

The frame 3 serves as a deposition preventing plate (shielding plate) and as a component supporting member in the vacuum chamber.

The frame 3 is provided (i) so as not to cover a vapor deposition particle injection path which connects an opening area 302 (in which the openings 301 are formed) in the mask 300 with injection holes 21a and 31a of the respective vapor deposition particle injecting devices 20 and 30 and (ii) so as to cover an area (e.g., surroundings of the vapor deposition particle injecting device 30 and the inner wall 2a) in the vacuum chamber 2 onto which area the vapor deposition particles are not intended to flow and attach (i.e., an area other than the injection path in which the vapor deposition particles need to flow).

According to the vapor deposition device 1, vapor deposition particles scattered from the vapor deposition particle injecting devices 20 and 30 are adjusted to scatter into the opening area 302 of the mask 300, and vapor deposition particles which are scattered out of the mask 300 are appropriately blocked by the frame 3 (see FIG. 2).

This makes it possible to prevent an unintended area other than the opening area 302 of the mask 300 from being polluted by attached vapor deposition particles.

The frame 3 includes a plurality of shelves 3a. For example, constituent members such as the movable supporting unit 4 and the shutter operating unit 6 in the vacuum chamber are held and fixed on the plurality of shelves 3a.

<Configuration of Movable Supporting Unit 4>

As above described, the mask 300 is fixed in close contact with the film formation surface 201 of the film formation substrate 200 with the fixing means (not illustrated).

The movable supporting unit 4 is a substrate moving unit which supports the film formation substrate 200 and the mask 300 in a movable (carriable) manner while keeping horizontal postures of the film formation substrate 200 and the mask 300.

The movable supporting unit 4 includes (i) a driving section made up of a motor (XYθ driving motor) such as a stepping motor (pulse motor), a roller, a gear, and the like and (ii) a drive control section such as a motor drive control section. The drive control section drives the driving section so that the film formation substrate 200 and the mask 300 are moved.

According to the example illustrated in FIG. 2, the movable supporting unit 4 carries (in-line carriage) the film formation substrate 200 (such as a TFT substrate) and the mask 300 in an X-axis direction on a YX-plane above the vapor deposition particle injecting devices 20 and 30, while holding the film formation substrate 200 so that the film formation surface 201 faces a mask surface of the mask 300, in which mask surface the openings are formed. The vapor deposition material is thus vapor deposited on the film formation surface 201 of the film formation substrate 200.

The film formation substrate 200 has an alignment marker (not illustrated) used to carry out an alignment between the mask 300 and the film formation substrate 200.

The movable supporting unit 4 carries out positional correction of the film formation substrate 200 by driving the motor (not illustrated) such as the stepping motor so that positional displacement of the film formation substrate 200 is corrected and the film formation substrate 200 is positioned properly.

<Configuration of Shutter 5>

The shutter 5 is provided between the mask 300 and the vapor deposition particle injecting device 30 (see FIG. 2). The shutter 5 is used to determine whether or not to inject vapor deposition particles toward the film formation substrate 200 in order to control vapor deposition particles injected from the vapor deposition particle injecting device 30 to reach or not to reach the mask 300.

In a case where a vapor deposition rate is stabilized or vapor deposition is not required, the shutter 5 prevents vapor deposition particles from being injected in the vacuum chamber 2.

The shutter 5 is provided, for example, such that the shutter 5 can be moved back and forth (can be inserted) between the mask 300 and the vapor deposition particle injecting devices 20 and 30 by the shutter operating unit 6. With the configuration, for example, it is possible to block the injection path of vapor deposition particles so that the vapor deposition particles do not reach the film formation substrate 200 while an alignment between the film formation substrate 200 and the mask 300 is being carried out.

Note that, while a film formation on the film formation substrate 200 is not carried out, the shutter 5 covers the injection holes 21a and 31a of the respective vapor deposition particle injecting devices 20 and 30, from which injection holes 21a and 31a vapor deposition particles (vapor deposition material) are injected.

<Configuration of Shutter Operating Unit 6>

The shutter operating unit 6 holds the shutter 5 (see FIG. 2) and operates the shutter 5 based on, for example, a vapor deposition OFF signal or a vapor deposition ON signal supplied from the control section (not illustrated) provided outside the vacuum chamber.

The shutter operating unit 6 includes, for example, a motor (not illustrated) and causes a motor drive control section (not illustrated) to drive the motor so as to operate (move) the shutter 5.

For example, the shutter operating unit 6 moves the shutter 5 in the X-axis direction based on a vapor deposition OFF signal supplied from the control section (not illustrated) so that the shutter 5 is moved to a location between the mask 300 and the vapor deposition particle injecting devices 20 and 30. This blocks the injection path of vapor deposition particles which are directed from the vapor deposition particle injecting devices 20 and 30 toward the mask 300.

Alternatively, the shutter operating unit 6 moves the shutter 5 in the X-axis direction based on a vapor deposition ON signal supplied from the control section (not illustrated) so that the shutter 5 is moved from the location between the mask 300 and the vapor deposition particle injecting devices 20 and 30. This opens the injection path of vapor deposition particles which are directed from the vapor deposition particle injecting devices 20 and 30 toward the mask 300.

By thus operating the shutter operating unit 6 so that the shutter 5 is inserted between the mask 300 and the vapor deposition particle injecting devices 20 and 30 as appropriate, it is possible to prevent vapor deposition on a superfluous area (in which a film is not intended to be formed) of the film formation substrate 200.

<Configuration of Vapor Deposition Particle Injecting Device Moving Unit 7>

The vapor deposition particle injecting device moving unit 7 includes (i) a stage 8 on which the vapor deposition particle injecting devices 20 and 30 are provided and (ii) an actuator 9 (see FIG. 2).

The stage 8 is a supporting base for supporting the vapor deposition particle injecting devices 20 and 30 and is placed on the actuator 9 which is provided on a bottom wall of the vacuum chamber 2. The actuator 9 is an X-axis driving actuator for moving the stage 8 in the X-axis direction.

Note, however, that the present embodiment is not limited to this. For example, the vapor deposition particle injecting devices 20 and 30 can be provided directly on the bottom wall of the vacuum chamber 2.

Alternatively, the vapor deposition particle injecting device moving unit 7 can include, (i) as the stage 8, a stage such as a stage that moves in X, Y, and Z directions and, (ii) as the actuator 9, a Z-axis driving actuator.

The XYZ stage supports the vapor deposition particle injecting devices 20 and 30 and includes a motor (not illustrated) such as an XYθ driving motor. With the configuration, the vapor deposition particle injecting devices 20 and 30 are moved by the motor which is driven by a motor drive control section (not illustrated).

The Z-axis driving actuator controls a gap (clearance) between the mask 300 and the vapor deposition particle injecting devices 20 and 30 by converting a control signal into a movement in the Z-axis direction that is perpendicular to a surface of the mask 300 in which surface the openings are formed.

The gap between the mask 300 and the vapor deposition particle injecting devices 20 and 30 can be set arbitrarily and is not limited to a particular one. Note, however, that the gap is preferably set as small as possible in order to enhance efficiency of utilization of the vapor deposition material. For example, the gap is set to approximately 100 mm.

As such, it is preferable that the vapor deposition particle injecting devices 20 and 30 are provided such that the vapor deposition particle injecting devices 20 and 30 can be moved by the vapor deposition particle injecting device moving unit 7 in any of the X-axis direction, the Y-axis direction, and the Z-axis direction.

<Configuration of Vapor Deposition Particle Injecting Devices 20 and 30>

The vapor deposition particle injecting devices 20 and 30 face the film formation substrate 200 via the mask 300.

The vapor deposition particle injecting devices 20 and 30 evaporate or sublimate, by heat, a vapor deposition material, which is a film formation material, in a high vacuum so as to inject the vapor deposition material such as an organic luminescent material in the form of vapor deposition particles.

In the present embodiment, an example is described in which the vapor deposition particle injecting devices 20 and 30 are located under the film formation substrate 200, and the vapor deposition particle injecting devices 20 and 30 upwardly vapor-deposit vapor deposition particles (i.e., up-deposition) onto the film formation surface 201, which faces downwards, of the film formation substrate 200 via the openings 301 of the mask 300 (see FIG. 2).

FIG. 1 is a cross-sectional view schematically illustrating a configuration of the vapor deposition particle injecting device 20 in accordance with the present embodiment.

Note that the vapor deposition particle injecting devices 20 and 30 have identical configurations as illustrated in FIG. 2. In view of this, the following description will discuss an example of the vapor deposition particle injecting device 20. Note, however, that the configuration of the vapor deposition particle injecting device 30 is of course equal to a configuration obtained by reading the reference numerals 20 through 26 as the respective reference numerals 30 through 36.

The vapor deposition particle injecting device 20 includes a holder 21 (housing), a crucible 22, plate members 23 through 25 (thin plate, inner plate), and a heat exchanger 26 (heating member) (see FIGS. 1 and 2).

The following description will discuss constituent members of the vapor deposition particle injecting device 20.

<Configuration of Holder 21>

The holder 21, which is a housing, contains and holds (i) the plurality of plate members (in the present embodiment, the plate members 23 through 25) which are arranged to constitute a plurality of stages and (ii) the crucible 22.

The holder 21 has, for example, a cylindrical shape or a quadrangle tubular shape. The holder 21 has a top wall in which an injection hole 21a is provided through which a gaseous vapor deposition material is to be injected outside.

<Configuration of Heat Exchanger 26>

The heat exchanger 26 is provided around the holder 21. The holder 21 is heated up by the heat exchanger 26, such as a heater or an electromagnetic induction unit, which is provided outside the holder 21.

<Configuration of Crucible 22>

The crucible 22 is a heating container for containing (storing) and heating the vapor deposition material. As the crucible 22, it is possible to employ an ordinary crucible which has been conventionally used as a vapor deposition source and is made of a material such as graphite, PBN (pyrolytic boron nitride), or metal.

Note that it is preferable that the holder 21 and the crucible 22 are made of materials having high thermal conductivity because conduction of heat from the heat exchanger 26, which is provided outside the holder 21, can be carried out efficiently.

By heating up the crucible 22 by the heat exchanger 26 via the holder 21, the vapor deposition material in the crucible 22 is evaporated (in a case where the vapor deposition material is a liquid material) or sublimated (in a case where the vapor deposition material is a solid material) into gas.

That is, the crucible 22 is used as a vapor deposition particle generating section for generating gaseous vapor deposition particles.

The crucible 22 (i) is provided on a bottom part (lowermost layer) of the holder 21 and (ii) has an opening in a top surface of the crucible 22.

The gaseous vapor deposition material is injected from the injection hole 21a of the holder 21 toward the film formation substrate 200.

<Configuration of Plate Members 23 Through 25>

In the holder 21, the plurality of plate members, each of which has an opening (through hole) penetrating in an up-and-down direction, are provided above the crucible 22 (i.e., between the crucible 22 and the injection hole 21a) so as to constitute a plurality of stages. The plurality of plate members overlap each other in a direction in which the openings are penetrating (penetrating direction) and are spaced from each other.

According to the present embodiment, the plate members 23 through 25 having respective openings 23a through 25a are provided in a vertical direction from the crucible 22 to the film formation substrate 200 (in a normal direction, i.e., in a direction from the vapor deposition source to the substrate) so as to overlap each other while being spaced from each other (see FIGS. 1 and 2). As such, four space layers partitioned by the plate members 23 through 25 are formed in the holder 21.

The holder 21 includes, for example, plate supporting members (not illustrated) for supporting the plate members 23 through 25. The plate members 23 through 25 are supported by the plate supporting members (not illustrated) which are provided in the holder 21.

The plate members 23 through 25 have a size and a planar shape which correspond to an inner diameter and a shape of the holder 21. In this case, an outer diameter of the plate members 23 through 25 is equal to the inner diameter of the holder 21.

Vapor deposition particles emitted from the crucible 22 are moved to an upper space layer (on a downstream side) via the openings 23a through 25a formed in the respective plate members 23 through 25.

In this case, the openings 23a through 25a formed in the respective plate members 23 through 25 and the injection hole 21a overlap each other in a direction perpendicular to opening planes of the openings 23a through 25a and the injection hole 21a (in other words, in a direction perpendicular to a substrate surface of the film formation substrate 200) (see FIG. 1). As such, the openings 23a through 25a and the injection hole 21a overlap each other when viewed in a direction perpendicular to the openings 23a through 25a and the injection hole 21a (that is, when viewed in a plan view).

Note that, in the present embodiment, an example is described in which the openings 23a through 25a have identical sizes, and center positions (centers of openings) of the respective openings 23a through 25a coincide with each other (see FIG. 1).

As such, the center positions of the openings 23a through 25a and the injection hole 21a coincide with each other when viewed in the direction perpendicular to the opening planes of the openings 23a through 25a and the injection hole 21a. With the configuration, the openings 23a through 25a and the injection hole 21a are always to have an overlapping area as indicated by an area A in FIG. 1.

Moreover, since the center positions of the openings 23a through 25a and the injection hole 21a coincide with each other, it is possible to cause vapor deposition flows, which pass through the openings 23a through 25a and the injection hole 21a, to become parallel flows. Further, it is possible to increase an apparent through hole length (nozzle length) in an opening direction of the openings 23a through 25a and the injection hole 21a. This allows an improvement in collimation (parallel flow) property of the vapor deposition flows by a nozzle length effect.

Note, however, that the present embodiment is not limited to this. That is, the center positions do not necessarily need to coincide with each other, and the openings 23a through 25a do not necessarily need to have identical sizes.

In a case where the openings 23a through 25a formed in the respective plate members 23 through 25 overlap each other, some of vapor deposition particles emitted from the crucible 22 are not to make contact with anywhere until being injected from the injection hole 21a. That is, according to the present embodiment, the vapor deposition particles can be emitted from the crucible 22 directly to the injection hole 21a via an area in which the openings 23a through 25a overlap each other.

The holder 21 has an inner wall 21b which is spaced apart from the openings 23a through 25a. In other words, the openings 23a through 25a of the respective plate members 23 through 25 are formed in locations which are spaced apart from the inner wall 21b of the holder 21.

In a case where the vapor deposition particle injecting device 20 having such a configuration is used, the vapor deposition material (vapor deposition particles) which has been evaporated or sublimated from the crucible 22 becomes (i) first vapor deposition particles which are emitted from the crucible 22 and then injected directly outside via the injection hole 21a without making contact with anywhere in the holder 21 and (ii) second vapor deposition particles which collide with the plate members 23 through 25 or the inner wall 21b (inner wall surface) of the holder 21.

The first vapor deposition particles are injected outside of the holder 21 (i.e., outside of the vapor deposition particle injecting device) without making contact with anywhere in the holder 21. In this case, a maximum injection angle θ₀ of the vapor deposition particles is restricted to θ₁ (i.e., θ₀=θ₁) (see FIG. 1).

In this case, the maximum injection angle θ₀ of the vapor deposition particles which are emitted from the crucible 22 and are then directly injected outside via the injection hole 21a is defined by a maximum angle between (i) an opening edge of a lowermost plate member which opening edge is closest to the area in which the injection hole 21a and the openings 23a through 25a of the respective plate members 23 through 25 overlap each other when viewed in the direction perpendicular to the opening planes of the injection hole 21a and the openings 23a through 25a and (ii) the injection hole 21a which overlaps with an opening having the opening edge.

The following description will discuss further details of this.

In a case where the vapor deposition particle injecting device 20 is divided (into two) by a center line passing through a center of the injection hole 21a as illustrated in FIG. 1, the area in which the openings 23a through 25a of the respective plate members 23 through 25 and the injection hole 21a overlap each other in the plan view is referred to as “area A”.

In a cross section obtained by dividing the vapor deposition particle injecting device 20 by the center line of the injection hole 21a, a lower end part of an opening edge of a lowermost plate member 23 is referred to as “opening edge B” which is located on a line H that connects (i) a lower end (lower opening edge 23a₁) of the opening edge of the lowermost plate member 23, which opening edge is on one of two opposite sides of the area A with (ii) an upper end part of an opening edge (i.e., upper opening edge 21a₁) of the injection hole 21a of the holder 21, which opening edge is on the other of the two opposite sides.

In the cross section obtained by dividing the vapor deposition particle injecting device 20 by the center line of the injection hole 21a, the upper end part of the opening edge (i.e., the upper opening edge 21a₁) of the injection hole 21a of the holder 21, which opening edge is on the other of the two opposite sides, is referred to as “opening edge C”.

In this case, the maximum injection angle θ₀ is an angle between a normal line (vertical line) passing through the opening edge B and a line connecting the opening edge B with the opening edge C (see FIG. 1).

According to the present embodiment, the openings 23a through 25a and the injection hole 21a have identical sizes and are concentrically arranged. With the configuration, opening edges of the openings 23a through 25a and of the injection hole 21a in the cross section obtained by dividing the vapor deposition particle injecting device 20 by the center line of the injection hole 21a are located in identical locations when viewed in the plan view.

In this case, the opening edge B is the lower end (lower opening edge 23a₁) of the opening edge, on one of the two opposite sides (e.g., on the left in a sheet on which FIG. 1 is shown) of the area A, of the opening 23a of the plate member 23 (first plate member) which is located at the lowermost stage, and the opening edge C is the upper opening edge 21a₁, on a side (e.g., on the right in the sheet on which FIG. 1 is shown) opposite to the opening edge B via the area A, of the injection hole 21a of the holder 21 which is located at the uppermost stage.

In other words, according to the present embodiment, the maximum injection angle θ₀ is the angle θ₁ between (i) a normal line with respect to the opening edge of the opening 23a on one of the two opposite sides in the cross section illustrated in FIG. 1 and (ii) the line H connecting the lower end (lower opening edge 23a₁) of the opening edge of the opening 23a with the upper opening edge 21a₁ which is located opposite to the opening edge via the area A.

In the above description, the lower opening edge 23a₁ on the left of the area A in FIG. 1 has been described as the opening edge B.

Note, however, that the same description is applicable to a case where a lower opening edge 23a₁ of the plate member 23 on the right of the area A in FIG. 1 is assumed to be the opening edge B, because the openings 23a through 25a and the injection hole 21a have identical sizes and the center positions of the openings 23a through 25a and the injection hole 21a coincide with each other in the example illustrated in FIG. 1.

From this, in the example illustrated in FIG. 1, a range W in which vapor deposition particles can be emitted from the crucible 22 and then injected directly outside via the injection hole 21a (i.e., a range in which vapor deposition particles can be emitted from a first space layer D, in which the crucible 22 is provided, in the holder 21 and then injected directly outside via the injection hole 21a) is obtained by expanding outwards (i.e., toward each of the two opposite sides) an injection hole width d3 (i.e., opening size, diameter) of the injection hole 21a by the angle θ₁ (i.e., θ₀) from a normal direction with respect to each of the opening edges of the injection hole 21a.

Therefore, the range W in which vapor deposition particles are emitted from the crucible 22 and then injected directly outside via the injection hole 21a can be arbitrarily set by changing the injection hole width d3 of the injection hole 21a and the angle θ₁ (θ₀).

According to the present embodiment, only one injection hole 21a is provided in the direction (i.e., the Y-axis direction) perpendicular to the substrate scanning direction (in other words, in the direction in which the plurality of openings 301 are arranged in the mask 300 as above described). This allows the range W, in which vapor deposition particles are emitted from the crucible 22 and then injected directly outside via the injection hole 21a, to be easily and arbitrarily set by changing the injection hole width d3 of the injection hole 21a and the angle θ₁ (θ₀). It is therefore possible to easily set and control a vapor deposition range.

In the above description, thicknesses of the plate members 23 through 25 are taken into consideration. Note, however, that it is preferable that the plate members 23 through 25 have thicknesses which are as small as possible so that vapor deposition particles are less likely to be reflected or scattered in the openings 23a through 25a.

Therefore, it is hardly necessary to consider the thicknesses of the plate members 23 through 25 in a practical use, and, as above described, the maximum injection angle θ₀ of the vapor deposition particles, which are emitted from the crucible 22 and then directly injected outside via the injection hole 21a, can be defined by the maximum angle between (i) an opening edge of a lowermost plate member which opening edge is closest to the area in which the injection hole 21a and the openings 23a through 25a of the respective plate members 23 through 25 overlap each other when viewed in the direction perpendicular to the opening planes of the injection hole 21a and the openings 23a through 25a and (ii) the injection hole 21a which overlaps with an opening having the opening edge.

Meanwhile, the second vapor deposition particles repeatedly collide with and scattered by the inner wall 21b of the holder 21 and adjacent plate members between the adjacent plate members.

Here, the four space layers partitioned by the plate members 23 through 25 in the holder 21 are referred to as follows: that is, (i) a space layer between the plate member 23 (first plate member) and the crucible 22 is referred to as “first space layer D”, (ii) a space layer between the plate member 24 (second plate member) and the plate member 23 is referred to as “second space layer E”, (iii) a space layer between the plate member 25 (third plate member) and the plate member 24 is referred to as “third space layer F”, and (iv) a space layer between the top wall of the holder 21 and the plate member 25 is referred to as “fourth space layer G”.

In the first space layer D, vapor deposition particles which are reflected and scattered by the plate member 23 or the inner wall 21b return to the crucible 22 or flow to an upper layer (upper part) via the opening 23a of the plate member 23 located in the upper part.

Here, the vapor deposition particles flown from the first space layer D to the upper part are then emitted from the injection hole 21a without making contact with anywhere in the holder 21 or caught between plate members in the upper layer, i.e., caught in any of the second space layer E through the fourth space layer G again. The vapor deposition particles caught between the plate members in the upper layer then repeat the process similar to that of the lower layer.

That is, the second vapor deposition particles are repeatedly reflected and scattered by any of the plate members 23 through 25 and the inner wall 21b in a similar manner in each of the upper layers, and are ultimately injected outside via the injection hole 21a.

According to the present embodiment, vapor deposition particles, which are reflected and scattered by the inner wall 21b in any of the first space layer D through the third space layer F (other than the fourth space layer G which is the uppermost layer), are not directly injected outside via the injection hole 21a (note that a bottom part of the crucible 22 is not considered as the inner wall surface).

In other words, a straight line that passes through (i) an arbitrary point on the inner wall 21b (inner wall surface) in any of the space layers other than the fourth space layer G which is the uppermost layer and (ii) the injection hole 21a intersects with any of the plate members 23 through 25.

In the second space layer E illustrated in FIG. 1, only vapor deposition particles which are reflected and scattered from a part indicated by “R2” can be directly injected outside via the injection hole 21a. In the third space layer F, only vapor deposition particles which are reflected and scattered from a part indicated by “R3” can be directly injected outside via the injection hole 21a.

That is, the ranges R2 and R3 are ranges, in respective of the second space layer E and the third space layer F, from which vapor deposition particles are directly injected outside via the injection hole 21a.

Here, assuming that the cross section obtained by dividing the vapor deposition particle injecting device 20 by the center line of the injection hole 21a has two sides which are opposite to each other via the area A, a range in which vapor deposition particles are injected from each space layer to outside of the injection hole 21a is indicated by an area between (I) a lower end of an opening edge of a lower plate member of the each space layer and (II) a point at which the lower plate member intersects with a line connecting (i) a lower end of an opening edge of an upper plate member adjacent to the lower plate member in the same space layer, which opening edge is on the same side as the opening edge of the lower plate member with (ii) an upper opening edge 21a₁ (i.e., the upper edge of opening on the opposite side via the area A) of the injection hole 21a.

As such, in each of the two opposite sides of the area A in the cross section of the vapor deposition particle injecting device 20 illustrated in FIG. 1, R2 indicates an area between (I) the lower end (i.e., the lower opening edge 23a₁) of the opening edge of the opening 23a of the plate member 23 and (II) a point J at which the plate member 23 intersects with a line I connecting (i) the lower end (i.e., a lower opening edge 24a₁) of the opening edge of the opening 24a of the plate member 24, which opening edge is on the same side as the opening edge of the plate member 23 with (ii) the upper opening edge 21a₁ of the injection hole 21a.

In each of the two opposite sides of the area A in the cross section of the vapor deposition particle injecting device 20 illustrated in FIG. 1, R3 indicates an area between (I) the lower end (i.e., the lower opening edge 24a₁) of the opening edge of the opening 24a of the plate member 24 and (II) a point L at which the plate member 23 intersects with a line K connecting (i) the lower end (i.e., a lower opening edge 25a₁) of the opening edge of the opening 25a of the plate member 25, which opening edge is on the same side as the opening edge of the plate member 24 with (ii) the injection hole 21a.

In FIG. 1, R2 and R3 are illustrated only on one of the two opposite sides of the area A. Note, however, that R2 and R3 on the other of the two opposite sides are determined in a similar manner.

In a case where (i) the opening edge of the upper plate member is closer to the area A than the opening edge of the lower plate member is (i.e., the opening edge of the upper plate member further protrudes toward the center of the opening than the opening edge of the lower plate member does) and (ii) the line connecting the lower opening edge of the lower plate member with the upper opening edge 21a₁ intersects with the upper plate member, in other words, in a case where the line connecting the lower opening edge of the upper plate member with the upper opening edge 21a₁ is closer to the area A than the opening edge of the opening of the lower plate member is (i.e., the line does not intersects with the lower plate member), vapor deposition particles, which are reflected and scattered by such upper and lower plate members and the inner wall 21b between the upper and lower plate members, will not be injected directly via the injection hole 21a but will be ultimately injected via the injection hole 21a after repeatedly reflected and scattered again by the inner wall 21b and plate members in the upper space layer(s) or will return to the crucible 22 again.

Note, however, that, in the fourth space layer G which is the uppermost layer, vapor deposition particles which are reflected and scattered by the inner wall 21b and the plate members in the fourth space layer G can be injected via the injection hole 21a.

As above described, the present embodiment is configured such that, in the first space layer D through the third space layer F, only some of vapor deposition particles, which are repeatedly reflected and scattered, are to be injected via the injection hole 21a.

In this case, a maximum injection angle of vapor deposition particles which are to be injected outside directly from the first space layer D via the injection hole 21a is restricted to θ₁, a maximum injection angle of vapor deposition particles which are to be injected outside directly from the second space layer E via the injection hole 21a is restricted to θ₂, and a maximum injection angle of vapor deposition particles which are to be injected outside directly from the third space layer F via the injection hole 21a is restricted to θ₃. Note that the angle θ₁ (=maximum injection angle θ₀) has already been described above.

The angle θ₂ is an angle between the normal line and the line I connecting the lower opening edge 24a₁ with the upper opening edge 21a₁, i.e., an angle between the line I and the normal line at the point J at which the line I intersects with the plate member 23.

The angle θ₃ is an angle between the normal line and the line K connecting the lower opening edge 25a₁ with the upper opening edge 21a₁, i.e., an angle between the line K and the normal line at the point L at which the line K intersects with the plate member 24.

As such, the maximum injection angles θ₂ and θ₃ of vapor deposition particles, which are to be injected outside directly from the second space layer E and the third space layer F via the injection hole 21a, are larger than the maximum injection angle θ₀ from the crucible 22 and are restricted as with the above described first space layer D.

As above described, according to the present embodiment, the plurality of plate members which have respective through holes as openings are arranged in the normal direction so as to constitute the plurality of stages in the holder 21. This allows an increase in ratio of vapor deposition particles which are injected at a smaller injection angle, and it is therefore possible to improve directivity.

Consequently, it is possible to reduce an influence of the inner wall 21b as much as possible, and it is therefore possible to suppress an increase in injection angle of vapor deposition particles which is caused by reflection and scattering of vapor deposition particles by the inner wall 21b.

According to the present embodiment, the inner wall 21b is sufficiently spaced apart from the openings of the plate members in each of the space layers. Specifically, as illustrated in FIG. 1 for example, a distance between the inner wall 21b and each of the opening edges of the openings 23a and 24a is larger than each of distances defined by R2 and R3 in respective of the second space layer E and the third space layer F.

This makes it possible to (i) suppress an increase in density of vapor deposition particles in the vicinity of the openings 23a through 25a and the injection hole 21a and (ii) avoid scattering of vapor deposition particles caused by collisions of the vapor deposition particles with each other.

Moreover, since the inner wall 21b extends far back from the injection hole 21a, it is possible to reduce a pressure of a vapor deposition flow in the vicinity of the injection hole 21a. This allows a reduction in scattering of vapor deposition particles caused by collisions of the vapor deposition particles with each other, and it is therefore possible to further improve directivity.

With the configuration, it is possible to improve directivity of the vapor deposition flow unlike the conventional vapor deposition particle injecting devices as disclosed in Patent Literatures 1 through 3.

Since vapor deposition particles can be injected outside directly from the crucible 22 via the injection hole 21a, it is possible to utilize vapor deposition particles that originally have directivity toward the film formation substrate 200, and it is therefore possible to further improve the directivity of the vapor deposition flow.

<Method for Determining Inner Wall Location of Holder 21 in Space Layer Other than Uppermost Layer>

An inner wall location of the holder 21 in a space layer other than the uppermost layer can be determined as described below.

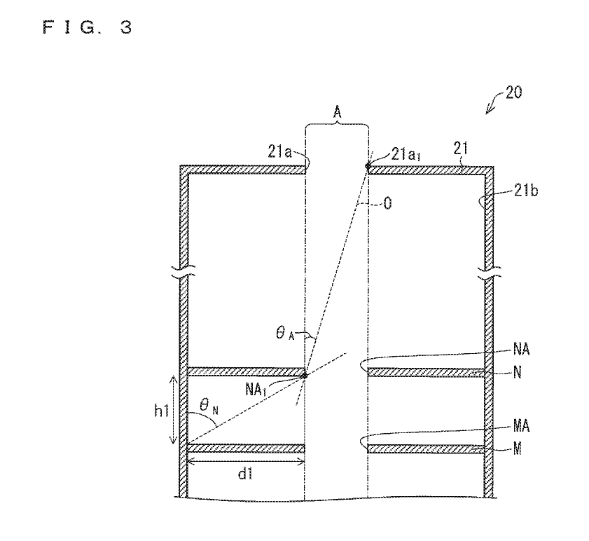

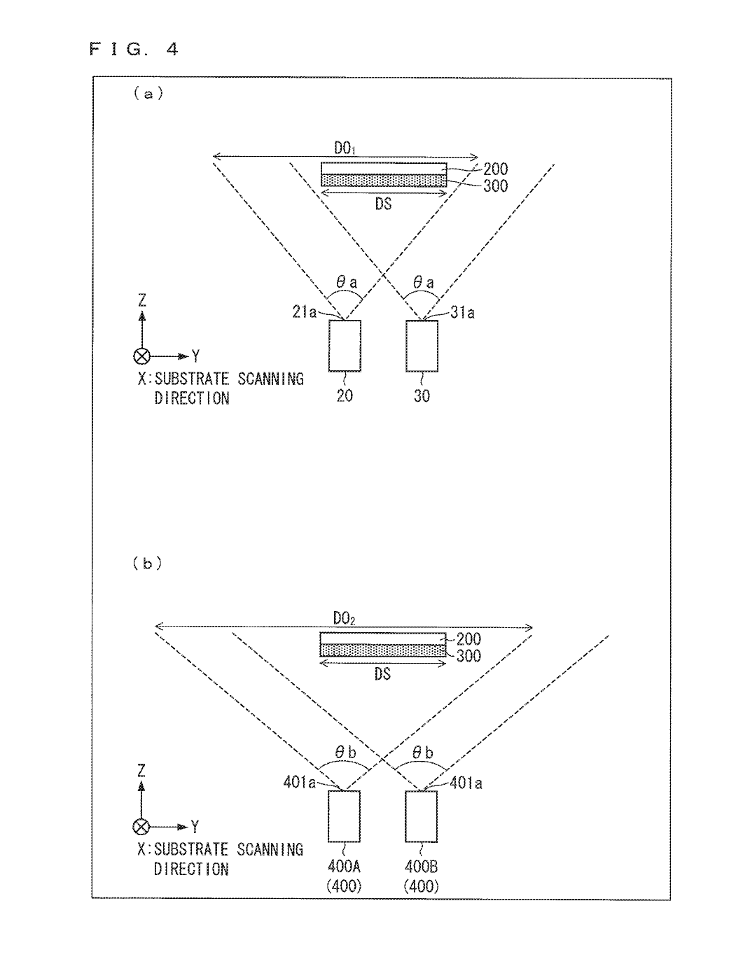

FIG. 3 is a cross-sectional view (i) for explaining how to determine an inner wall location of the holder 21 in a space layer other than the uppermost layer and (ii) illustrating a main part of the vapor deposition particle injecting device 20.

The following description will also discuss an example of the vapor deposition particle injecting device 20. Note, however, that the configuration of the vapor deposition particle injecting device 30 is of course equal to a configuration obtained by reading the reference numerals 20 through 26 as the respective reference numerals 30 through 36.

In FIG. 3, a sign M indicates an arbitrary lower plate member in the holder 21, and a sign N indicates an upper plate member adjacent to the plate member M in the holder 21. Moreover, signs MA and NA indicate openings (through holes) which are provided in the respective plate members M and N.

Here, in a space layer between the plate member M and the plate member N, a maximum angle between the inner wall 21b and a line connecting a lower end of the inner wall 21b with a lower opening edge NA₁ of the opening NA, which lower opening edge NA₁ is located closest to the inner wall 21b, is defined as θ_{N}. Moreover, a maximum angle (maximum injection angle) between the lower opening edge NA₁ and the injection hole 21a when viewed in the direction perpendicular to opening planes of the injection hole 21a and the openings MA and NA is defined as θ_{A}.

That is, in the cross section obtained by dividing the vapor deposition particle injecting device 20 by the center line of the injection hole 21a illustrated in FIG. 3, the maximum injection angle θ_{A} is an angle between (i) the normal line (vertical line) passing through the lower opening edge NA₁ on one of two opposite sides of the area A (in which the openings MA and NA and the injection hole 21a overlap each other in the example of FIG. 3) and (ii) a line O connecting the lower opening edge NA₁ and the upper opening edge 21a₁ on the other of the two opposite sides.

In this case, the thicknesses of the plate members 23 through 25 are taken into consideration. Note, however, that, as early described, it is hardly necessary to consider the thicknesses of the plate members 23 through 25 in a practical use.

In the cross section illustrated in FIG. 3, for example, one (1) injection hole 21a, one (1) opening MA, and one (1) opening NA are provided, and up-deposition is carried out.

Note, however, that the present invention, in practice, encompasses cases where (i) a plurality of injection holes 21a, a plurality of openings MA, and a plurality of openings NA are provided and (ii) down-deposition or side-deposition is carried out as later described. Note that the down-deposition and the side-deposition will be described later.

As such, the angle θ_{N} is defined as a maximum angle between (i) the inner wall 21b between the plate members M and N (which are adjacent ones of the plurality of plate members in the holder 21) and (ii) the line connecting (a) the end part of the inner wall 21b on a vapor deposition particle generating section side (i.e., a crucible 22 side) between the plate members M and N and (b) the opening edge of the opening NA (of the plate member N on an injection hole 21a side) which opening edge is closest to the inner wall 21b between the plate members M and N.

The angle θ_{A} is defined as a maximum angle which is formed, when viewed in the direction perpendicular to the opening planes of the injection hole 21a and the openings MA and NA, between (i) the opening edge (i.e., the opening edge of the opening NA which opening edge is closest to the inner wall 21b between the plate members M and N) and (ii) the injection hole 21a that overlaps with the opening NA having the opening edge.

In this case, if the angles θ_{N} and θ_{A} satisfy the following formula (2):

θ_{N}>θ_{A} (2)

vapor deposition particles will not be injected outside directly from the inner wall 21b in a space layer other than the uppermost layer via the injection hole 21a.

In a space layer that satisfies the formula (2), vapor deposition particles, which have collided with the inner wall 21b and been scattered, collide with the plate members M and N or the inner wall 21b again or are moved to other layer(s) via the openings MA and NA.

This makes it possible to suppress or prevent an influence of the inner wall 21b on vapor deposition particles which are to be emitted outwards (i.e., out of the injection hole 21a) from the vapor deposition particle injecting device 20.

In a case where a depth from the opening NA to the inner wall 21b (i.e., an inner surface of a lateral wall of the holder 21) is d1 and a distance between the plate member M and the plate member N in the normal direction (i.e., a distance between adjacent plate members) is h1, the above configuration can be achieved by determining (adjusting) the depth d and the distance h1 so that the formula (2) is satisfied.

Note that the distance (space) h1 between the adjacent plate members in the normal direction and the depth d1 can vary for each space layer and can be changed as appropriate.

<Method for Designing Uppermost Space Layer>

In the fourth space layer G which is located in the uppermost part, it is difficult to suppress or prevent an influence of the inner wall 21b on vapor deposition particles which are to be emitted outside the vapor deposition particle injecting device 20.

If a plate thickness of the holder 21, which has the injection hole 21a, is increased, it is possible to prevent vapor deposition particles, which have been reflected and scattered by the inner wall 21b, from being directly injected outside via the injection hole 21a. Note, however, that this is not preferable because vapor deposition particles will be reflected and scattered by a lateral surface of the injection hole 21a.

However, as the depth from the injection hole 21a to the inner wall 21b (in this case, the inner surface of the lateral wall of the holder 21) becomes larger, an apparent area of the injection hole 21a becomes smaller when viewed from the inner wall 21b. Consequently, vapor deposition particles, which are injected outside from the inner wall of the holder 21 via the injection hole, are further reduced.

With regard to the inner wall 21b in the fourth space layer G which is the uppermost space layer, in a case where, for example as illustrated in FIG. 1, (i) a distance in the normal direction is h2 between the uppermost plate member (the plate member 25 in the example illustrated in FIG. 1) and the top wall of the holder 21 in which top wall the injection hole is formed and (ii) the depth from the injection hole 21a to the inner wall 21b (i.e., the inner surface of the lateral wall of the holder 21) is h2, as the distance h2 is made shorter and as the depth d2 is made larger (i.e., as d2/h2 is made larger), the apparent cross-sectional area of the injection hole 21a viewed from the inner wall 21b becomes smaller. Under the circumstances, it is preferable that d2/h2 of the uppermost space layer is set as large as possible.

Therefore, it is preferable that the depth d2 to the inner wall 21b in the uppermost space layer is set as large as possible.

It is preferable that the plate members 23 through 25 in which the respective openings 23a through 25a are formed and the top wall of the holder 21 in which the injection hole 21a is formed are made as thin as possible in order to prevent, as much as possible, vapor deposition particles from being reflected and scattered in the openings 23a through 25a and the injection hole 21a.

The thickness of the plate members 23 through 25 and the top wall of the holder 21 and the depth d2 are not limited to particular ones. Note, however, that such thicknesses and the depth d2 are preferably designed, in accordance with conditions such as a formation method, formation material, a size of the film formation substrate 200, and a strength for maintaining a shape, so that d2/h2 becomes larger as much as possible.

<Method for Forming Vapor-Deposited Film with Use of Two Vapor Deposition Sources>

The vapor deposition device 1 of the present embodiment includes two vapor deposition sources, i.e., the vapor deposition particle injecting devices 20 and 30 (see FIG. 2). According to the vapor deposition device 1 illustrated in FIG. 2, the vapor deposition material is evaporated or sublimated from the vapor deposition particle injecting devices 20 and 30 which are vapor deposition sources so that vapor deposition is carried out on the film formation substrate 200 via the vapor deposition mask 300.

The following description will discuss a method for forming a vapor-deposited film with the use of the two vapor deposition sources as above described.

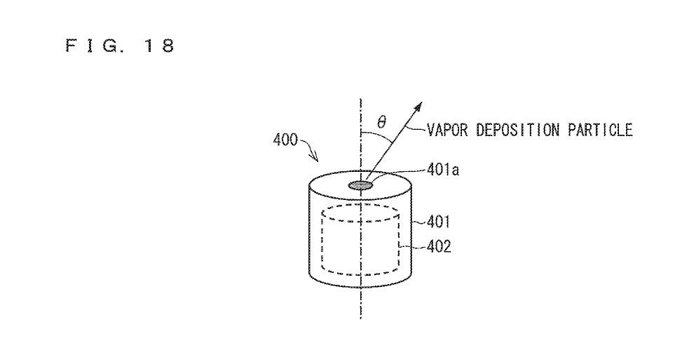

(a) and (b) of FIG. 4 are a view schematically illustrating how a vapor-deposited film is formed with the use of the two vapor deposition sources. (a) of FIG. 4 illustrates a case where the vapor deposition particle injecting devices 20 and 30 of the present embodiment are used as the vapor deposition sources (i.e., a case of high directivity), and (b) of FIG. 4 illustrates a case where vapor deposition particle injecting devices 400A and 400B, which have a configuration identical with that of a general vapor deposition particle injecting device 400 illustrated in FIG. 17, are used as the vapor deposition sources (i.e., a case of low directivity).

As illustrated in (a) and (b) of FIG. 4, in a case where vapor deposition is carried out with the use of the two vapor deposition sources, vapor deposition on the film formation substrate 200 is carried out in an area in which spread ranges of vapor deposition particles, which are injected from the two vapor deposition sources, overlap each other. Otherwise, a thickness of a vapor-deposited film on the film formation substrate 200 becomes uneven.

The two vapor deposition sources can inject respective different vapor deposition materials. In such a case, if vapor deposition is not carried out on the film formation substrate 200 in the area in which the spread ranges of vapor deposition particles overlap with each other, a thickness of the vapor-deposited film becomes uneven and also the two vapor deposition materials cannot be mixed.

According to the present embodiment, the spread of vapor deposition particles is defined as, for example, an angle range in which an amount of vapor deposition particles is at least 1% as compared to a largest amount of distributed vapor deposition particles.

According to the general vapor deposition source, an applied amount of vapor deposition particles (i.e., density of vapor deposition particles) is largest directly above the injection hole 401a (i.e., injection angle θ=0), and, as the injection angle θ becomes larger, the applied amount of vapor deposition particles (i.e., density of vapor deposition particles) becomes smaller (see FIG. 19).

In a case where the general vapor deposition particle injecting devices 400A and 400B are employed, directivity is low and a spread angle of vapor deposition particles is large (see (b) of FIG. 4).

Under the conventional circumstances, vapor deposition particles are injected on the film formation substrate 200 at the injection angle of θb as illustrated in (b) of FIG. 4, and therefore only a vapor deposition flow, with which a vapor deposition area DS of the film formation substrate 200 is irradiated, could have been utilized among a vapor deposition flow that spreads in a range DO₂.

In a case where a conventional material utilization efficiency is indicated by η2, the material utilization efficiency η2 has been DS/D0₂.

However, according to the present embodiment, the directivity of the vapor deposition flow is improved as illustrated in (b) of FIG. 4, and the injection angle θ of vapor deposition particles is smaller (i.e., θa). This allows the vapor deposition flow to spread merely to a range DO₁.

According to the configuration, in a case where the material utilization efficiency obtained by using the vapor deposition particle injecting devices 20 and 30 of the present embodiment is η1, the material utilization efficiency η1 is DS/DO₁ (note that DO₁<DO₂), that is, the material utilization efficiency is improved.

By taking into consideration that the directivity is improved also in a perpendicular direction with respect to a sheet on which FIG. 4 is shown (i.e., in the X-axis direction which is the scanning direction), the material utilization efficiency of the present embodiment becomes a two-dimensional ratio of η1²/η2², which is further improved as compared with the conventional material utilization efficiency. For example, in a case where DO₂:DO₁ is 2:1, η2²:η1² becomes 1:4, that is, the material utilization efficiency is improved four times.

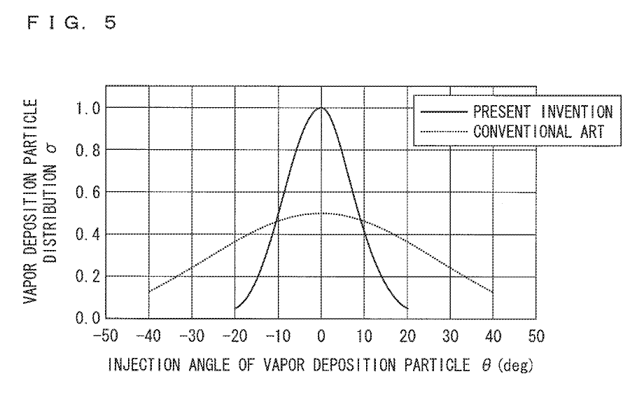

FIG. 5 is a graph illustrating a relation between a vapor deposition particle distribution σ and an injection angle θ (θa, θb) of vapor deposition particles, in cases where the vapor deposition particle injecting devices 20 and 30 (the present embodiment) and the vapor deposition particle injecting devices 400A and 400B (conventional art) are used as the vapor deposition sources.

FIG. 5 illustrates, as a vapor deposition particle distribution σ, a vapor deposition density distribution of vapor deposition particles obtained in a case where the vapor deposition particle injecting devices 20 and 30 are employed and a central film thickness of a vapor-deposited film is normalized as 100% (σ=1.0) when θ=0.

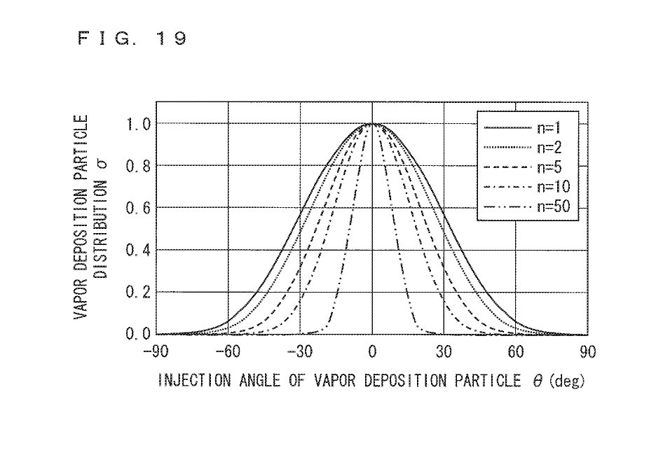

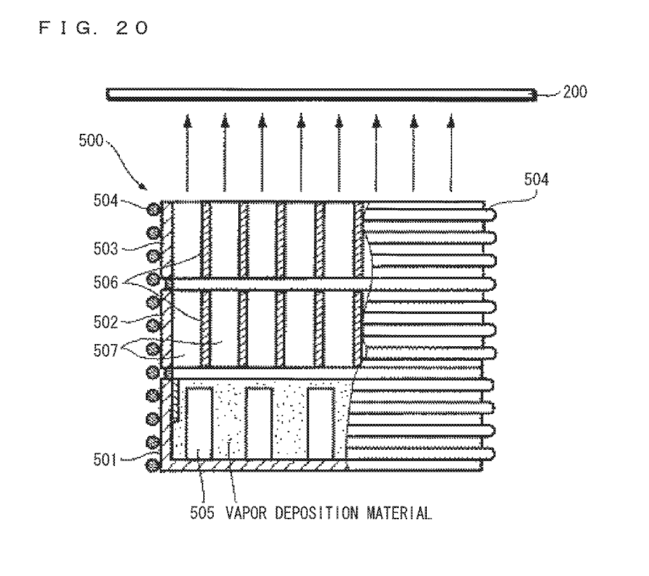

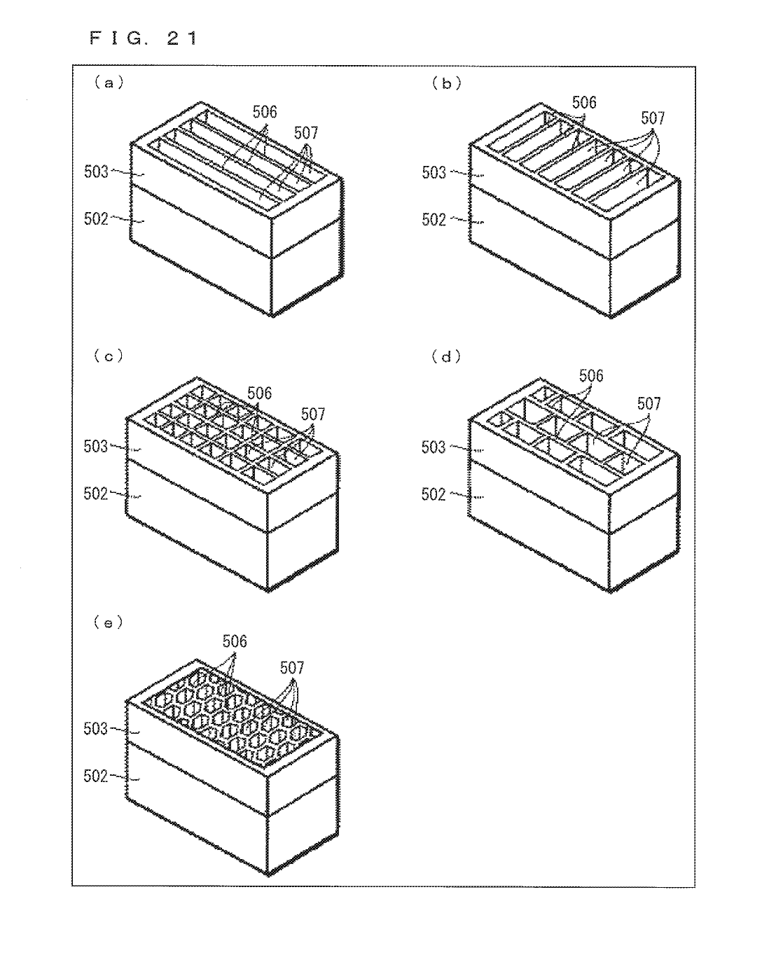

Note that, as early described, θ indicates an angle between the normal direction and injected vapor deposition particles (see FIG. 18).

As a measurement condition, a non-alkali glass substrate was used as the film formation substrate 200 and Alq₃ (sublimate temperature: 305° C.) was used as the vapor deposition material, as with the measurement illustrated in FIG. 19. A distance from the non-alkali glass substrate to each of the injection holes 21a, 31a, and 401a was 125 mm, a film formation rate was 0.1 nm/sec, and a degree of vacuum in the vacuum chamber was 1×10⁻³ Pa or less. Moreover, the film formation was carried out so that a film formed on the non-alkali glass substrate had a central film thickness of 100 nm.

Conditions of the vapor deposition particle injecting devices 20 and 30 were as follows: that is, h1=12 mm, h2=6 mm, d1=d2=12 mm, d3=2 mm, θ₁ (θ₀)=3.6°, θ₂=5.9°, θ₃=15.9°, a length of the injection holes 21a and 31a (i.e., a thickness of a layer in which the injection holes 21a and 31a were formed)=0.5 mm, a length of the openings 23a through 25a in the normal direction (i.e., a thickness of the plate members 23 through 25)=0.5 mm, and a height of the holder 21=80 mm.

As illustrated in FIG. 5, in a case where the vapor deposition particle injecting devices 20 and 30 of the present embodiment are employed as the vapor deposition sources, the distribution of the vapor deposition flow (vapor deposition particles) becomes smaller than that of the conventional technique, and consequently the density of vapor deposition particles is improved.

That is, according to the present embodiment, the directivity is improved and the spread angle of vapor deposition particles can be made smaller, as compared with the conventional technique. Therefore, in a case where vapor deposition flows, which are identical in amount, are injected from respective injection holes of the vapor deposition sources, the density of vapor deposition particles becomes higher, and accordingly a vapor deposition speed is improved.

The following description will discuss a method for forming a film formation pattern with the use of the vapor deposition device 1. Specifically, the following description will discuss, as an example of a vapor deposition method of the present embodiment, a method for manufacturing an RGB full-color organic EL display device which is a bottom emission device in which light is extracted from a TFT substrate side.

<Overall Configuration of Organic EL Display Device>

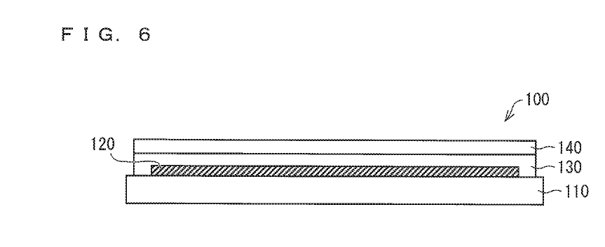

FIG. 6 is a cross-sectional view schematically illustrating a configuration of an organic EL display device.

An organic EL display device 100 includes a TFT substrate 110, an organic EL element 120, an adhesive layer 130, and a sealing substrate 140 (see FIG. 6).

On the TFT substrate 110, TFTs or the like are provided in respective pixel areas as switching elements.

The organic EL elements 120 are arranged in a matrix manner in a display area of the TFT substrate 110.

The TFT substrate 110 on which the organic EL elements 120 are provided is adhered to the sealing substrate 140 via the adhesive layer 130 or the like.

The following description will discuss, in detail, configurations of the TFT substrate 110 and the organic EL element 120 in the organic EL display device 100.

<Configuration of TFT Substrate 110>

FIG. 7 is a cross-sectional view schematically illustrating a configuration of the organic EL elements 120 which constitute a display section of the organic EL display device 100.

In the TFT substrate 110, TFTs 112 (switching element), wires 113, an interlayer insulating film 114, edge covers 115, and the like are provided on a transparent insulating substrate 111 such as a glass substrate (see FIG. 7).

The organic EL display device 100 is a full-color active matrix organic EL display device, and pixels 101R, 101G, and 101B are (i) constituted by respective organic EL elements 120 for red (R), green (G), and blue (B) in respective areas surrounded by the wires 113 on the insulating substrate 111 and (ii) arranged in a matrix manner.

The TFTs 112 are provided for the respective pixels 101R, 101G, and 101B. Note that each of the TFTs has a conventionally known configuration. Therefore, layers in each of the TFTs 112 are not illustrated in the drawings and descriptions of such layers are omitted.

The interlayer insulating film 114 is stacked on an entire area of the insulating substrate 111 so as to cover the TFTs 112 and the wires 113.

There are provided on the interlayer insulating film 114 first electrodes 121 of the organic EL elements 120.

The interlayer insulating film 114 has contact holes 114a for electrically connecting the first electrodes 121 of the organic EL elements 120 to the TFTs 112. This electrically connects the TFTs 112 to the organic EL elements 120 via the contact holes 114a.

The edge covers 115 are insulating layers for preventing the first electrodes 121 from short-circuiting with corresponding second electrodes 126 in the respective organic EL elements 120 due to, for example, (i) a reduction in thickness of the organic EL layer in end parts of the first electrodes 121 or (ii) an electric field concentration.

The edge covers 115 are so formed on the interlayer insulating film 114 as to cover end parts of the first electrodes 121.

The first electrodes 121 are exposed in areas which are not covered with the edge covers 115 (see FIG. 7). The areas in which the first electrodes 121 are exposed serve as light-emitting sections in the respective pixels 101R, 101G, and 101B.

In other words, the pixels 101R, 101G, and 101B are isolated from one another by the insulating edge covers 115. The edge covers 115 thus function as element isolation films as well.

<Method for Manufacturing TFT Substrate 110>

The insulating substrate 111 can be made of, for example, non-alkali glass or plastic. In the present embodiment, non-alkali glass having a plate thickness of 0.7 mm is used.

A known photosensitive resin can be employed as each of the interlayer insulating film 114 and the edge covers 115. Examples of such a known photosensitive resin encompass an acrylic resin and a polyimide resin.

Each of the TFTs 112 is produced by a known method. Note that the present embodiment is exemplified by the active matrix organic EL display device 100 in which the TFTs 112 are provided for the respective pixels 101R, 101G, and 101B, as above described.

Note, however, that the present embodiment is not limited to this, and the present embodiment is applicable to a method for manufacturing a passive matrix organic EL display device in which no TFT is provided.

<Configuration of Organic EL Element 120>

The organic EL element 120 is a light-emitting element capable of high-luminance light emission based on low-voltage direct-current driving, and includes in its structure the first electrode 121, the organic EL layer, and the second electrode 126 which are stacked in this order.

The first electrode 121 is a layer having the function of injecting (supplying) positive holes into the organic EL layer. The first electrode 121 is, as described above, connected to the TFT 112 via the contact hole 114a.

The organic EL layer provided between the first electrode 121 and the second electrode 126 includes, as illustrated in FIG. 7 for example, a hole injection layer/hole transfer layer 122, luminescent layers 123R, 123G, and 123B, an electron transfer layer 124, and an electron injection layer 125, which are formed in this order from the first electrode 121 side.

The organic EL layer can, as needed, further include a carrier blocking layer (not illustrated) for blocking a flow of carriers such as positive holes and electrons. A single layer can have a plurality of functions. For example, it is possible to provide a single layer that serves as both a hole injection layer and a hole transfer layer.

The above stack order intends to use (i) the first electrode 121 as an anode and (ii) the second electrode 126 as a cathode. The stack order of the organic EL layer is reversed in the case where the first electrode 121 serves as a cathode and the second electrode 126 serves as an anode.

The hole injection layer has the function of increasing efficiency in injecting positive holes from the first electrode 121 into the organic EL layer. The hole transfer layer has the function of increasing efficiency in transferring positive holes to the luminescent layers 123R, 123G, and 123B. The hole injection layer/hole transfer layer 122 is so formed uniformly throughout the entire display area of the TFT substrate 110 as to cover the first electrode 121 and the edge cover 115.

The present embodiment describes a case involving, as the hole injection layer and the hole transfer layer, a hole injection layer/hole transfer layer 122 that integrally combines a hole injection layer with a hole transfer layer as described above. The present embodiment is, however, not limited to such an arrangement: The hole injection layer and the hole transfer layer may be provided as separate layers independent of each other.

There are provided on the hole injection layer/hole transfer layer 122 the luminescent layers 123R, 123G, and 123B for the respective pixels 101R, 101G, and 101B.

The luminescent layers 123R, 123G, and 123B are each a layer that has the function of emitting light by recombining (i) positive holes injected from the first electrode 121 side with (ii) electrons injected from the second electrode 126 side. The luminescent layers 123R, 123G, and 123B are each made of a material with high light emission efficiency, such as a low-molecular fluorescent pigment and a metal complex.

The electron transfer layer 124 is a layer that has the function of increasing efficiency in transferring electrons to the luminescent layers 123R, 123G, and 123B. The electron injection layer 125 is a layer that has the function of increasing efficiency in injecting electrons from the second electrode 126 into the organic EL layer.

The electron transfer layer 124 is so provided on the luminescent layers 123R, 123G, and 123B and the hole injection layer/hole transfer layer 122 uniformly throughout the entire display area of the TFT substrate 110 as to cover the luminescent layers 123R, 123G, and 123B and the hole injection layer/hole transfer layer 122.

The electron injection layer 125 is so provided on the electron transfer layer 124 uniformly throughout the entire display area of the TFT substrate 110 as to cover the electron transfer layer 124.

The electron transfer layer 124 and the electron injection layer 125 may be provided either (i) as separate layers independent of each other as described above or (ii) integrally with each other. In other words, the organic EL display device 100 may include an electron transfer layer/electron injection layer instead of the electron transfer layer 124 and the electron injection layer 125.

The second electrode 126 is a layer having the function of injecting electrons into the organic EL layer including the above organic layers. The second electrode 126 is so provided on the electron injection layer 125 uniformly throughout the entire display area of the TFT substrate 110 as to cover the electron injection layer 125.

The organic layers other than the luminescent layers 123R, 123G, and 123B are not essential for the organic EL layer, and may thus be included as appropriate in accordance with a required property of the organic EL element 120.

A single layer can have a plurality of functions, as with the hole injection layer/hole transfer layer 122 or the electron transfer layer/electron injection layer.

The organic EL layer may further include a carrier blocking layer according to need. The organic EL layer can, for example, additionally include, as a carrier blocking layer, a hole blocking layer between (i) the electron transfer layer 124 and (ii) the luminescent layers 123R, 123G, and 123B to prevent positive holes from transferring to the electron transfer layer 124 and thus to improve light emission efficiency.

According to the configuration above described, layers other than the first electrode 121 (anode), the second electrode 126 (cathode), and the luminescent layers 123R, 123G, and 123B can be provided as appropriate.

<Method for Manufacturing Organic EL Element 120>

The first electrodes 121 are formed by (i) depositing an electrode material by a method such as sputtering and (ii) then patterning the electrode material in shapes for respective pixels 101R, 101G, and 101B by photolithography and etching.

The first electrodes 121 can be made of any of various electrically conductive materials. Note, however, that the first electrodes 121 need to be transparent or semi-transparent in a case where the organic EL display device 100 is a bottom emission organic EL element in which light is emitted towards the insulating substrate 111 side.

Meanwhile, the second electrode 126 needs to be transparent or semi-transparent in a case where the organic EL display device 100 is a top emission organic EL element in which light is emitted from a side opposite to the substrate side.

The conductive film material for the first electrode 121 and the second electrode 126 is, for example, (i) a transparent conductive material such as ITO (indium tin oxide), IZO (indium zinc oxide), and gallium-added zinc oxide (GZO) or (ii) a metal material such as gold (Au), nickel (Ni), and platinum (Pt).

The first electrode 121 and the second electrode 126 can be formed by a method such as a sputtering method, a vacuum vapor deposition method, a chemical vapor deposition (CVD) method, a plasma CVD method, and a printing method. For example, the first electrode 121 can be formed by the use of the vapor deposition device 1 which will be later described.

The organic EL layer can be made of a known material. For example, each of the luminescent layers 123R, 123G, and 123B is made of a single material or made of a host material mixed with another material as a guest material or a dopant.

The hole injection layer and the hole transfer layer or the hole injection layer/hole transfer layer 122 can be made of, for example, a material such as anthracene, azatriphenylene, fluorenone, hydrazone, stilbene, triphenylene, benzine, styryl amine, triphenylamine, porphyrin, triazole, imidazole, oxadiazole, oxazole, polyarylalkane, phenylenediamine, arylamine, or a derivative of any of the above, a monomer, an oligomer, or a polymer of a chain-like or cyclic conjugated system, such as a thiophene compound, a polysilane compound, a vinylcarbazole compound, or an aniline compound.

The luminescent layers 123R, 123G, and 123B are each made of a material, such as a low-molecular fluorescent pigment or a metal complex, which has high light emission efficiency. For example, the luminescent layers 123R, 123G, and 123B are each made of a material such as anthracene, naphthalene, indene, phenanthrene, pyrene, naphthacene, triphenylene, perylene, picene, fluoranthene, acephenanthrylene, pentaphene, pentacene, coronene, butadiene, coumarin, acridine, stilbene, a derivative of any of the above, a tris(8-quinolinate)aluminum complex, a bis(benzoquinolinate) beryllium complex, a tri(dibenzoylmethyl) phenanthroline europium complex, ditoluyl vinyl biphenyl, hydroxyphenyl oxazole, or hydroxyphenyl thiazole.

Each of the electron transfer layer 124 and the electron injection layer 125 or the electron transfer layer/electron injection layer can be made of, for example, a material such as a tris(8-quinolinate)aluminum complex, an oxadiazole derivative, a triazole derivative, a phenylquinoxaline derivative, or a silole derivative.

<Method for Forming Film Formation Pattern by Vacuum Vapor Deposition Method>

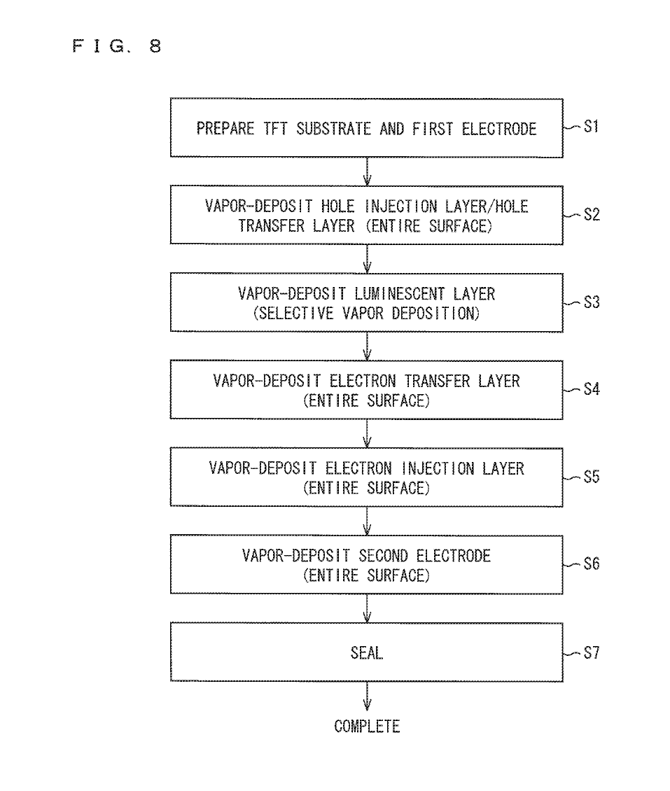

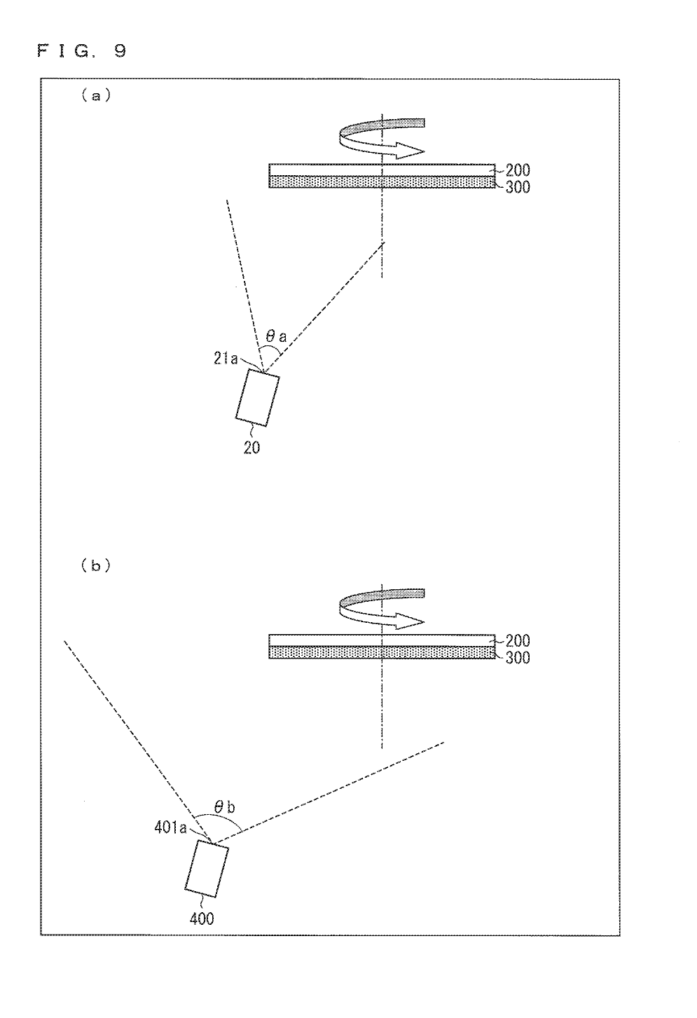

The following description will discuss a method for forming a film formation pattern with the use of a vacuum vapor deposition method, mainly with reference to FIG. 8.

Note that the description below discusses an example in which (i) the TFT substrate 110 is employed as the film formation substrate 200, (ii) an organic luminescent material is employed as a vapor deposition material, and (iii) an organic EL layer is formed as a vapor-deposited film on the film formation substrate 200, on which the first electrode 121 has been formed, with the use of the vacuum vapor deposition method.

According to the full-color organic EL display device 100, for example, the pixels 101R, 101G, and 101B, which are made up of the respective organic EL elements 120 having the respective luminescent layers 123R for red (R), 123G for green (G), and 123B for blue (B), are arranged in a matrix manner as above described.

Note that it is of course possible to provide luminescent layers for, for example, cyan (C), magenta (M), and yellow (Y), instead of the luminescent layers 123R, 123G, and 123B for the respective red (R), green (G), and blue (B). Alternatively, it is possible to provide luminescent layers for respective red (R), green (G), blue (B), and yellow (Y).

According to the organic EL display device 100 having such a configuration, a color image is displayed by causing the organic EL elements 120 to selectively emit light at intended luminance with the use of the TFTs 112.

Under the circumstances, in a case where the organic EL display device 100 is manufactured, it is necessary to form luminescent layers, each of which is made of an organic luminescent material for emitting colored light, for the respective organic EL elements 120 in a predetermined pattern on the film formation substrate 200.

As early described, the openings 301 having an intended shape are provided in the mask 300 at intended locations. The mask 300 is fixed in close contact with the film formation surface 201 of the film formation substrate 200 (see FIG. 2).

On the opposite side of the film formation substrate 200 via the mask 300, the vapor deposition particle injecting devices 20 and 30 are provided as the vapor deposition sources so as to face the film formation surface 201 of the film formation substrate 200.

In a case where the organic EL display device 100 is manufactured, the organic luminescent material is vapor deposited or sublimated into gas in a high vacuum so that the organic luminescent material is injected from the vapor deposition particle injecting devices 20 and 30 as gaseous vapor deposition particles.

The vapor deposition material, which has been injected from the vapor deposition particle injecting devices 20 and 30 as the vapor deposition particles, is vapor deposited on the film formation substrate 200 via the openings 301 provided in the mask 300.

This allows an organic film, which has an intended film formation pattern, to be vapor deposited as a vapor-deposited film only in intended locations on the film formation substrate 200 which locations correspond to the openings 301. Note that the vapor deposition is carried out for each color of the luminescent layer (this process is referred to as “selective vapor deposition”).

For example, in a case of the hole injection layer/hole transfer layer 122 illustrated in FIG. 7, film formation is carried out on the entire display section, and therefore an open mask, which has only openings corresponding to the entire display section and to areas in which the film formation is required, is employed as the vapor deposition mask 300.

Note that the same applies to the electron transfer layer 124, the electron injection layer 125, and the second electrode 126.

In a case where the luminescent layer 123R (see FIG. 7) corresponding to a pixel for displaying red is formed, film formation is carried out with the use of, as the vapor deposition mask 300, a fine mask having an opening corresponding only to an area in which a red luminescent material is to be vapor deposited.

<Flow of Manufacturing Organic EL Display Device 100>

FIG. 8 is a flowchart illustrating, in a processing order, processes of manufacturing the organic EL display device 100.

First, a TFT substrate 110 is prepared, and a first electrode 121 is formed on the TFT substrate 110 (step S1). Note that the TFT substrate 110 can be prepared with the use of a known technique.

Then, a hole injection layer and a hole transfer layer are formed in an entire pixel area on the TFT substrate 110, on which the first electrode 121 has been formed, by a vacuum vapor deposition method with the use of an open mask serving as the vapor deposition mask 300 (step S2). Note that a hole injection layer/hole transfer layer 122 can be formed instead of the hole injection layer and the hole transfer layer, as above described.

Next, luminescent layers 123R, 123G, and 123B are formed by carrying out selective vapor deposition by the vacuum vapor deposition method with the use of a fine mask serving as the vapor deposition mask 300 (step S3). This forms patterned films corresponding to the respective pixels 101R, 101G, and 101B.

Subsequently, an electron transfer layer 124, an electron injection layer 125, and a second electrode 126 are sequentially formed on the TFT substrate 110, on which the luminescent layers 123R, 123G, and 123B have been formed, in the entire pixel area by the vacuum vapor deposition method with the use of an open mask serving as the vapor deposition mask 300 (steps S4 through S6).

The substrate, on which the vapor depositions have been carried out as above described, is sealed in an area (display section) corresponding to the organic EL element 120 so that the organic EL element 120 will not be deteriorated by moisture and oxygen in the atmosphere (step S7).

Examples of the sealing encompass (i) a method in which a film, which hardly allows moisture and oxygen to pass through, is formed by a CVD method or the like and (ii) a method in which a glass substrate or the like is adhered by an adhesive agent or the like.

By thus carrying out the above described processes, the organic EL display device 100 is produced. The organic EL display device 100 can carry out an intended display by causing the organic EL elements 120 in the respective pixels to emit light in response to electric currents supplied from a driving circuit provided outside the organic EL display device 100.

<Main Points>

According to the present embodiment, as above described, the plate members 23 through 25 are provided in the holder 21 so as to be spaced from each other in the normal direction (i.e., so as to constitute the plurality of stages) and the plate members 23 through 25 have the respective openings 23a through 25a which overlap with the injection hole 21a in the plan view. In this arrangement, accordingly, the through holes are lined up from the crucible 22 in each of the vapor deposition particle injecting devices 20 and 30.

According to the present embodiment, therefore, vapor deposition particles can directly reach the injection hole 21a from the crucible 22 via the area in which the openings 23a through 25a overlap with each other. The maximum injection angle θ₀, at which the vapor deposition particles are injected outside via the injection hole 21a without making contact with anywhere in the holder 21, is restricted to the angle θ₁ as above described.

This allows an increase in ratio of vapor deposition particles which are moved at a small injection angle towards the upper layer via the openings 23a through 25a. It is therefore possible to improve directivity.

According to the configuration, it is possible to increase an apparent through hole length (nozzle length) in the opening direction of the injection hole 21a (i.e., the direction from the crucible 22 to the film formation substrate 200).

Further, each of the vapor deposition particle injecting devices 20 and 30 does not have a narrow space like a pipe. Therefore, density of vapor deposition particles is not increased in the vicinity of the openings 23a through 25a and the injection hole 21a, and it is therefore possible to reduce a frequency with which vapor deposition particles collide with each other.

According to the vapor deposition particle injecting devices 20 and 30, therefore, it is possible to suppress or prevent collision and scattering of vapor deposition particles and to improve collimation (parallel flow) property of vapor deposition flows by utilizing a nozzle length effect.

As such, according to the vapor deposition particle injecting devices 20 and 30, it is possible to improve directivity of vapor deposition particles with a simple structure.

By employing the vapor deposition particle injecting devices 20 and 30, distribution of a vapor deposition flow (vapor deposition particles) becomes smaller than that of a conventional technique. Consequently, it is possible to reduce an amount of vapor deposition particles which are to be vapor deposited in an unintended area, and it is therefore possible to improve material utilization efficiency.

According to the present embodiment, by employing the vapor deposition particle injecting devices 20 and 30, the directivity is improved and the spread angle of vapor deposition particles can be made smaller, as compared with the conventional technique. Therefore, even in a case where a vapor deposition flow, which is identical in amount with that of the conventional technique, is injected, the density of vapor deposition particles becomes higher than that of the conventional technique, and accordingly a vapor deposition speed is improved.

The inner wall surface of the holder 21 is arranged away from the openings 23a through 25a of the respective plate members 23 through 25, which are thin plates.

According to the present embodiment, therefore, vapor deposition particles which have been reflected and scattered by the inner wall 21b between adjacent plate members, in other words, vapor deposition particles which have been reflected and scattered by the inner wall surface of the holder 21 in the space layers other than the fourth space layer (i.e., the uppermost layer) will not be directly injected outside via the injection hole 21a. This reduces an amount of vapor deposition particles which are scattered from the inner wall surface of the holder 21 and are then directly injected.

Consequently, a component ratio of vapor deposition particles in the vertical direction (i.e., the direction from the crucible 22 to the film formation substrate 200) is improved and a spread of vapor deposition particles is reduced. This allows an improvement in material utilization efficiency, and accordingly cost of the organic EL display device is lowered.

Note that Patent Literature 2 discloses that an inner plate having at least one hole is provided in a space layer in a crucible.

According to the technique of Patent Literature 2, however, in a case where a metal such as Mg (magnesium) which easily reacts with oxygen is employed as a vapor deposition material, a metal oxide is filtered by utilizing a difference in vaporization temperature between the metal such as Mg and the metal oxide, in order to prevent (i) an increase in resistance of a cathode due to vapor deposition of the metal oxide on the film formation substrate and (ii) a dark spot defect caused by short-circuit between the anode and the cathode. With the technique of Patent Literature 2, the vapor deposition of the metal oxide on the film formation substrate is prevented.

In view of this, according to Patent Literature 2, the holes in the respective inner plates are arranged so as not to face each other by, for example, forming the holes in respective different locations in the respective inner plates so that a metal oxide which has passed through a hole of a lowermost inner plate can be filtered by an upper inner plate.

As such, according to Patent Literature 2, there is no area in which the holes in the respective inner plates overlap each other. Moreover, as with Patent Literature 1, Patent Literature 2 is silent about a configuration for eliminating (i) an influence of scattering caused by the inner wall surface of the vapor deposition source and (ii) an influence of scattering caused by an increase in density of vapor deposition particles. Therefore, Patent Literature 2 cannot solve such problems at all.

Patent Literature 3 discloses that a dispersion and transmission plate, in which a transmission hole is formed, is provided in a diffusion space in a vapor deposition material injecting container having a plurality of emission holes serving as injection holes of vapor deposition particles.

However, Patent Literature 3 is accomplished to solve the following problem: that is, in a case where an emission hole is provided in a location of a top surface plate of the vapor deposition material injecting container which location faces an outlet of a path via which the vapor deposition material is supplied to the vapor deposition material injecting container, an amount of vapor deposition particles which are emitted through the emission hole becomes larger than that of vapor deposition particles which are emitted through emission holes provided in other parts, because density of vapor deposition particles emitted to the diffusion space via the path is increased at the outlet of the path.

In view of this, a reflecting section having a diameter several times larger than of an opening plane of the outlet is provided on the dispersion and transmission plate in a location facing the outlet of the path. The reflecting section is formed in a face plate shape having no transmission hole.

According to the configuration of Patent Literature 3, vapor deposition particles emitted from the outlet of the path are reflected by the reflecting section, and vapor deposition particles are thus controlled in being emitted via the emission hole which is formed in a part of the top surface plate of the vapor deposition material injecting container which part (i) is located above the reflecting section and (ii) faces the outlet.

As such, the transmission hole provided in the dispersion and transmission plate of Patent Literature 3 does not overlap with the emission hole.

As with Patent Literatures 1 and 2, Patent Literature 3 is silent about the configuration for eliminating (i) an influence of scattering caused by the inner wall surface of the vapor deposition source and (ii) an influence of scattering caused by an increase in density of vapor deposition particles. On the contrary, according to Patent Literature 3, the reflecting section is provided on the dispersion and transmission plate in the location facing the outlet of the path (i.e., in the center of the dispersion and transmission plate), and the transmission hole is provided around the reflecting section. That is, the transmission hole is provided in the vicinity of the inner wall surface of the vapor deposition material injecting container.

Therefore, as with Patent Literatures 1 and 2, Patent Literature 3 cannot solve the problems of (i) the influence of scattering caused by the inner wall surface of the vapor deposition source and (ii) the influence of scattering caused by the increase in density of vapor deposition particles.

<Directivity and Material Utilization Efficiency in Case where Single Vapor Deposition Source is Provided>

As above described, the present embodiment has been exemplified by the case where the two vapor deposition sources are employed.

Note, however, that the present embodiment is not limited to this, and it is clear that a similar effect can be brought about in a case where a single vapor deposition source is employed.

(a) and (b) of FIG. 9 are a view schematically illustrating how a vapor-deposited film is formed with the use of one (1) vapor deposition source. (a) of FIG. 9 illustrates a case where the vapor deposition particle injecting device 20 of the present embodiment is used as the vapor deposition source (i.e., a case of high directivity), and (b) of FIG. 9 illustrates a case where the general vapor deposition particle injecting device 400 illustrated in FIG. 17 is used as the vapor deposition source (i.e., a case of low directivity).

In a case where the one (1) vapor deposition source is employed as illustrated in (a) and (b) of FIG. 9, a method is suitably employed in which the film formation substrate 200 is rotated in order to maintain uniformity of a thickness of a vapor-deposited film formed on the film formation substrate 200.

This is because, in general, a vapor deposition flow has a convex distribution as illustrated in FIG. 18, and the distribution needs to be equalized on the film formation substrate 200.

As illustrated in (a) and (b) of FIG. 9, a ratio of injected vapor deposition particles which reach the film formation substrate 200 is higher in the case of the high directivity illustrated in (a) of FIG. 9 than the case of the low directivity illustrated in (b) of FIG. 9. From this, it is clear that the material utilization efficiency and the vapor deposition speed can be improved in the case of the high directivity.

<Auxiliary Plate>

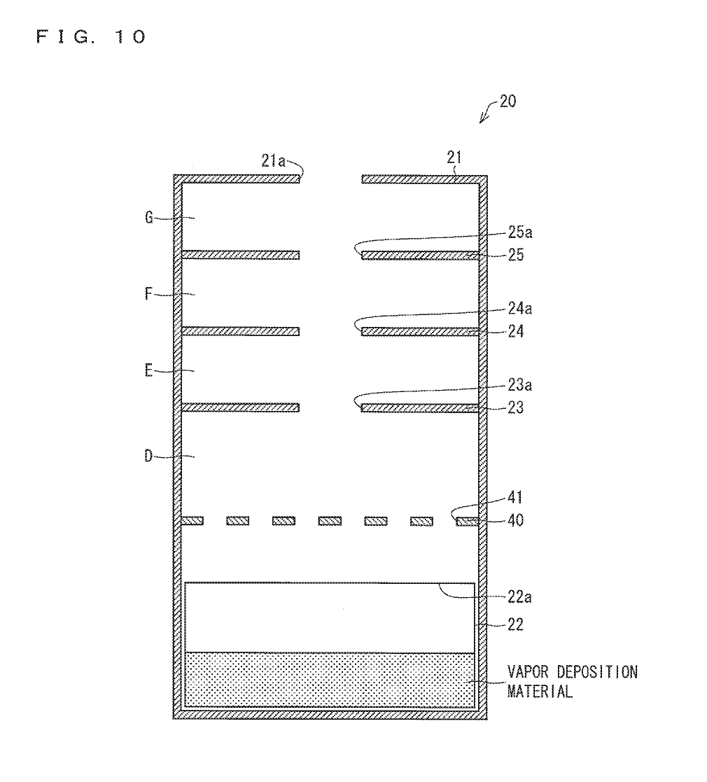

FIG. 10 is a cross-sectional view illustrating an example in which a mesh-like auxiliary plate 40 is provided in the holder 21 in the vapor deposition particle injecting device 20.

Note that the following description will discuss an example of the vapor deposition particle injecting device 20 with reference to FIG. 10. Note, however, that the configuration of the vapor deposition particle injecting device 30 is of course equal to a configuration obtained by reading the reference numerals 20 through 26 as the respective reference numerals 30 through 36.

An auxiliary plate 40, which has a plurality of small holes 41 (through holes) whose diameter is smaller than those of the injection hole 21a and of the openings 23a through 25a of the respective plate members 23 through 25, can be provided in the vicinity of the crucible 22, specifically, between the crucible 22 and the lowermost plate member 23 in the vapor deposition particle injecting device 20 (see FIG. 10).

In a case where the auxiliary plate 40, which has the plurality of small holes 41, is provided between the crucible 22 and the lowermost plate member 23, it is possible (i) to equalize density of vapor deposition particles emitted from different locations in the crucible 22 and (ii) to prevent aggregated vapor deposition particles from being (a) emitted from the crucible 22 and ultimately (b) injected via the injection hole 21a as a cluster.

Note that even in the case where the auxiliary plate 40 is provided between the crucible 22 and the lowermost plate member 23, it is possible to obtain vapor deposition particles that (i) travel from a surface of the auxiliary plate 40 and then directly injected through the injection hole 21a or (ii) are emitted from the crucible 22 and then directly injected through the injection hole 21a via the small holes 41 in the auxiliary plate 40.

Therefore, in this case also, it is possible to bring about the effect of the present embodiment.

Note that the small holes 41 in the auxiliary plate 40 are not limited in particular in size (mesh size, opening width), shape, and arrangement. Moreover, the small holes 41 do not necessarily need to overlap with the plate members 23 through 25 and the injection hole 21a when the auxiliary plate 40 is viewed in its plan view.

Examples of the auxiliary plate 40 encompass a mesh plate and a punched plate.

It is preferable that the size (pore diameter, opening width) of the small holes 41 in the auxiliary plate 40 is set to, for example, a diameter range between 0.1 mm and 1 mm. In a case where the diameter is smaller than 0.1 mm, the small holes 41 may clog with the vapor deposition material. In a case where the diameter is larger than 1 mm, the vapor deposition material may be emitted through the injection hole 21a as a cluster, i.e., the auxiliary plate may not function. It is preferable that the area A formed by the plate members 23 through 25 and the injection hole 21a has an opening width falling within a diameter range between 1 mm and 10 mm. Moreover, it is preferable that the injection hole width d3 of the injection hole 21a falls within a diameter range between 1 mm and 10 mm. In a case where the diameter is smaller than 1 mm, (i) a sufficient vapor deposition speed may not be obtained and (ii) scattering of vapor deposition particles may be increased due to an increase in collision of the vapor deposition particles. In a case where the diameter is larger than 10 mm, the vapor deposition particle injecting device 20 may become too large in size.

The auxiliary plate 40 and the plate members 23 through 25 can be made of a material which is, for example, identical with the material of the holder 21. It is preferable that thermal conductivity of the material of the auxiliary plate 40 and the plate members 23 through 25 is as high as that of the material of the holder 21. In a case where the thermal conductivity is low, the small holes 41 and the area A may clog with an attached vapor deposition material. In order to prevent a chemical reaction with the vapor deposition material, it is preferable that the auxiliary plate 40, the plate members 23 through 25, and the holder 21 are made of identical materials. The auxiliary plate 40 and the plate members 23 through 25 are heated up together with the holder 21. In this case, however, the inner wall surface of the holder 21 is located away from the openings 23a through 25a of the respective plate members 23 through 25 as above described, and therefore the problem of the regulating plate of Patent Literature 1 does not occur.

<Down-Deposition>

The present embodiment has been exemplified above by the case in which (i) the vapor deposition particle injecting devices 20 and 30 are provided below the film formation substrate 200 and (ii) the up-deposition is carried out via the openings 301 in the mask 300 by the vapor deposition particle injecting devices 20 and 30 which inject vapor deposition particles upwards. Note, however, that the present embodiment is not limited to this.

For example, it is possible that the vapor deposition particle injecting devices 20 and 30 are provided above the film formation substrate 200 and carry out vapor deposition on the film formation substrate 200 via the openings 301 in the mask 300 by injecting vapor deposition particles downwards (down-deposition).

In a case where the down-deposition is carried out, for example, an evaporated or sublimated vapor deposition material can be supplied to the holders 21 and 31 via respective load-lock pipes connected with the holders 21 and 31, instead of employing the configuration in which vapor deposition materials, which are directly stored in the crucibles 22 and 32 of the respective vapor deposition particle injecting devices 20 and 30, are heated up.

In a case where the down-deposition is employed as a vapor deposition method, a pattern with high definition can be formed accurately on the entire surface of the film formation substrate 200, without using means, such as an electrostatic chuck, for suppressing self-weight bending.

<Side-Deposition>

Alternatively, for example, each of the vapor deposition particle injecting devices 20 and 30 can have a mechanism for injecting vapor deposition particles in a lateral direction. In such a case, vapor deposition particles are vapor-deposited in the lateral direction on the film formation substrate 200 via the mask 300 (side-deposition) while the film formation surface 201 of the film formation substrate 200 lies in the vertical direction so that the film formation surface 201 faces the vapor deposition particle injecting devices 20 and 30.

Note that, also in a case where the side-position is carried out, for example, an evaporated or sublimated vapor deposition material can be supplied to the holders 21 and 31 via respective load-lock pipes connected with the holders 21 and 31, instead of employing the configuration in which vapor deposition materials, which are directly stored in the crucibles 22 and 32 of the respective vapor deposition particle injecting devices 20 and 30, are heated up.

<Other Modification Example>

The present embodiment has dealt with an example in which the three plate members are provided in each of the holders 21 and 31. Note, however, that the present embodiment is not limited to this. It is also possible to employ a configuration in which two plate members are provided or a configuration in which four or more plate members are provided.

The larger number of stages (the larger number of layers) produces a higher effect of the present embodiment, but may result in an increase in size of the vapor deposition source. The increase in size of the vapor deposition source may cause a problem concerning device design and necessitate a high-power heating device. The number of stages of the plate members is therefore determined in consideration of these matters.

The shape (planar shape) of openings of the respective plate members is not limited to a circular shape, but can be any of various shapes such as a rectangular shape.

The number of openings provided in each of the plate members is not limited to 1. Each of the plate members may have a plurality of openings.

That is, the through holes (i.e., the openings of the plate members and an injection hole) of the vapor deposition source may be aligned one-dimensionally (i.e., in a linear manner) or may be aligned two-dimensionally (i.e., in a planar manner).

For example, as described in embodiments described later, the larger number of injection holes allows a vapor deposition device to be applied to a film formation substrate 200 having a larger area, in a case where the film formation substrate 200 and the mask 300 are moved with respect to each other in a single direction.

Not only the through holes but also the vapor deposition source itself may be disposed also in a normal direction with respect to a sheet on which the drawings are shown (may be two-dimensionally aligned). Also in this case, vapor deposition is carried out in a region in which spread ranges of vapor deposition particles injected from respective vapor deposition sources overlap each other. The film formation substrate 200 may be scanned in normal direction with respect to the sheet on which the drawings are shown.

The present embodiment has dealt with an example in which (i) the organic EL display device 100 includes the TFT substrate 110 (ii) and organic layers are formed on the TFT substrate 110. Note, however, that the present invention is not limited to this. It is also possible to employ an arrangement in which (i) the organic EL display device 100 includes, instead of the TFT substrate 110, a TFT-free passive-type substrate on which organic layers are to be formed and (ii) the passive-type substrate is used as the film formation substrate 200.

The present embodiment has dealt with an example in which organic layers are formed on the TFT substrate 110 as described above. Note, however, that the present embodiment is not limited to this. The present embodiment is suitably applicable also to a case where an electrode pattern is formed instead of organic layers.

The vapor deposition particle injecting devices 20 and 30 and the vapor deposition device 1 are suitably applicable to every kinds of manufacturing methods and devices for forming a patterned film by vapor deposition, in addition to the method for manufacturing the organic EL display device 100. The vapor deposition particle injecting devices 20 and 30 and the vapor deposition device 1 are suitably applicable especially to a vapor deposition method which requires a vapor deposition source having high directivity.

The vapor deposition particle injecting devices 20 and 30 and the vapor deposition device 1 are suitably applicable, for example, to manufacturing of functional devices such as an organic thin film transistor, in addition to manufacturing of the organic EL display device 100.

### Embodiment 2

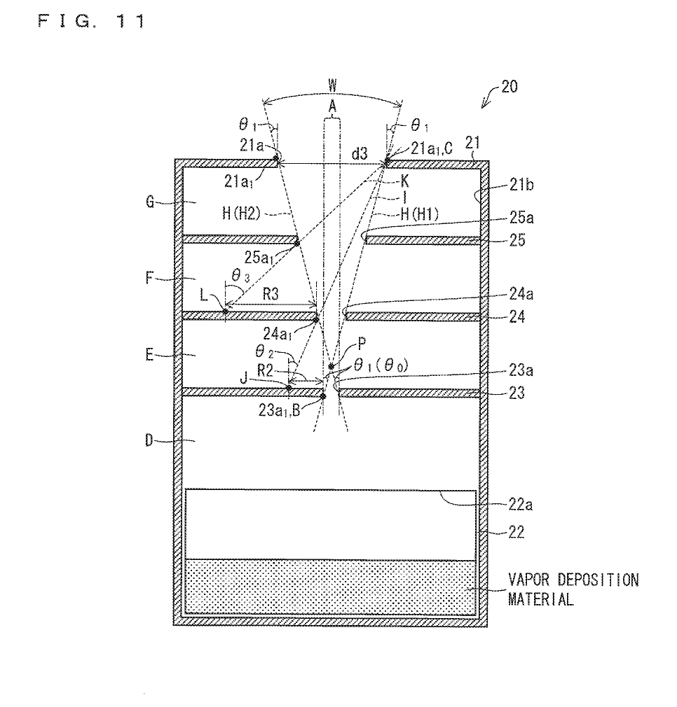

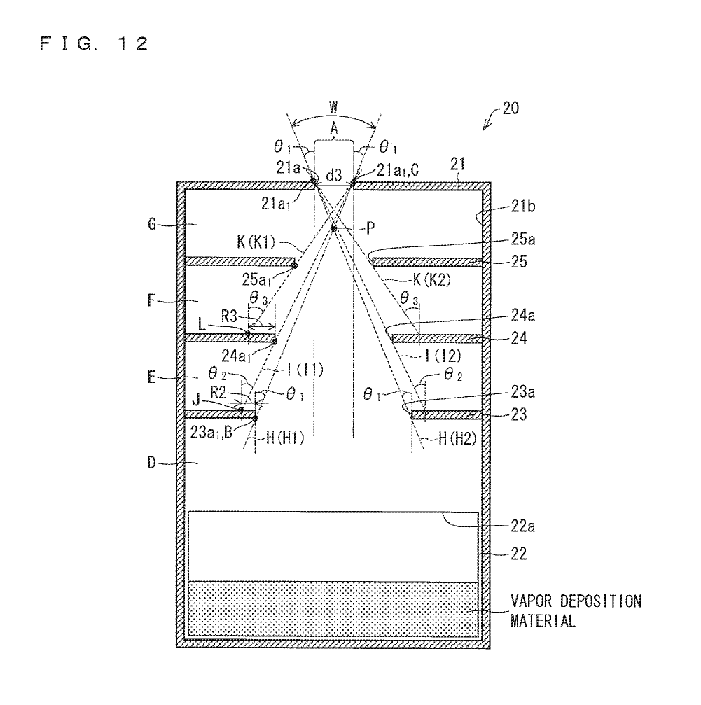

The present embodiment is described below mainly with reference to FIG. 11.

The present embodiment mainly describes differences from Embodiment 1. Note that members that have identical functions to those of Embodiment 1 are given identical reference numerals, and are not explained repeatedly.

<Configuration of Vapor Deposition Particle Injecting Devices 20 and 30>

FIG. 11 is a cross-sectional view schematically illustrating a configuration of a vapor deposition particle injecting device 20 in accordance with the present embodiment.

FIG. 11 also illustrates, as an example, the vapor deposition particle injecting device 20. Note, however, that the configuration of the vapor deposition particle injecting device 30 is of course equal to a configuration obtained by reading the reference numerals 20 through 26 as the respective reference numerals 30 through 36.

In FIG. 11, illustration of a heat exchanger 26 is omitted.

The vapor deposition particle injecting device 20 in accordance with the present embodiment is arranged such that through holes (openings of at least two plate members and an injection hole 21a) in a vapor deposition source have respective opening sizes which become larger as a distance from an uppermost layer (i.e., a distance from the injection hole 21a) becomes shorter.

In the example shown in FIG. 11, openings 23a through 25a of respective plate members 23 through 25 and the injection hole 21a have respective opening sizes which become larger as a distance from the injection hole 21a becomes shorter.

An angle formed by connecting the through holes (the openings 23a through 25a and the injection hole 21a) coincides with a desired injection angle of vapor deposition particles. In other words, the sizes of the openings 23a through 25a and the injection hole 21a are determined in accordance with the injection angle of the vapor deposition particles to be injected from the vapor deposition particle injecting device 20.

The configuration of the vapor deposition particle injecting device 20 in accordance with the present embodiment is identical to that of Embodiment 1 except for the points described above.

From this, in the example illustrated in FIG. 11, a range W in which vapor deposition particles can be injected from a crucible 22 directly to outside via the injection hole 21a (i.e., a range in which vapor deposition particles can be injected from a first space layer D, in which the crucible 22 is provided, in a holder 21 directly to outside via the injection hole 21a) is obtained by extending outwards (i.e., toward each of the two opposite sides) an injection hole width d3 (opening size, diameter) of the injection hole 21a by the angle θ₁ (i.e., θ₀) from a normal direction with respect to each of the opening edges of the injection hole 21a.

In the present embodiment, however, d3 is larger than that in the vapor deposition particle injecting device 20 illustrated in FIG. 1 (see FIG. 11). Also in the present embodiment, the range W in which vapor deposition particles are injected from the crucible 22 directly to outside via the injection hole 21a can be arbitrarily set by changing the injection hole width d3 of the injection hole 21a and the angle θ₁ (θ₀).

In the vapor deposition particle injecting device 20 illustrated in FIG. 11, sizes (ranges) of R2 and R3 are larger than those in the vapor deposition particle injecting device 20 illustrated in FIG. 1.

According to the present embodiment, it is therefore possible (i) to allow vapor deposition particles to be injected from the crucible 22 directly to outside of the injection hole 21a via the opening 23a of the lowermost plate member 23 without being hindered by thin plates (plates in the vicinity of the openings 24a and 25a and the injection hole 21a, i.e., the plate members 24 and 25 and a top wall of the holder 21) which specify the openings 24a and 25a and the injection hole 21a in upper stages, respectively, and (ii) to increase an amount of the vapor deposition particles injected from space layers via the through holes to outside of the injection hole 21a.

This makes it possible to further improve vapor deposition speed as compared with Embodiment 1.

Depending on design, there are cases where an opening of a plate member (e.g., the opening 24a of the plate member 24) located above the lowermost plate member 23 is smaller than the opening 23a of the lowermost plate member 23.

This depends on location of an intersection P of (i) a line H (line H1) connecting an opening edge, on one of two opposite sides (on the left in FIG. 11) of the area A, of the opening 23a of the lowermost plate member 23 and an opening edge, on the other of the two opposite sides (on the right in FIG. 11), of the injection hole 21a and (ii) a line H (line H2) connecting opening edges that are opposite, via the region A, to the opening edges defining the line H1, i.e., an opening edge, on the other of the two opposite sides (on the right in FIG. 11), of the opening 23a of the lowermost plate member 23 and an opening edge, on the one of two opposite sides (on the left in FIG. 11), of the injection hole 21a.

Therefore, such cases are also assumed in which the through holes become smaller first and then become larger as a distance from the uppermost layer becomes shorter.

That is, in the present embodiment, out of the injection hole 21a and the openings 23a through 25a of the respective plate members 23 through 25, the injection hole 21a and at least some of the openings 23a through 25a which overlap each other when viewed in a direction perpendicular to opening planes of the injection hole 21a and of the openings 23a through 25a have respective opening diameters which become larger as the distance from the injection hole 21a becomes shorter.

In other words, openings of respective plate members and the injection hole 21a are formed so that openings of at least two of the plate members the injection hole 21a and have respective opening diameters which become larger as a distance from the injection hole 21a becomes shorter.

<Manufacturing of Vapor Deposition Particle Injecting Devices 20 and 30>

The vapor deposition particle injecting devices 20 and 30 in accordance with the present embodiment can be designed and manufactured as described below. Note that the following description also takes, as an example, the vapor deposition particle injecting device 20.

First, a size (the injection hole width d3) of the injection hole 21a and θ₀ illustrated in FIG. 11 are determined.

Next, auxiliary lines (i.e., the lines H1 and H2) are drawn from the opening edges of the injection hole 21a so as to form an angle of θ₀.

Then, the plate members 23 through 25 are designed and disposed so that the opening edges of the openings 23a through 25a are located on the auxiliary lines (i.e., the lines H1 and H2). Note that the plate members 23 through 25 are designed and disposed so as to satisfy the formula (2).

### Embodiment 3

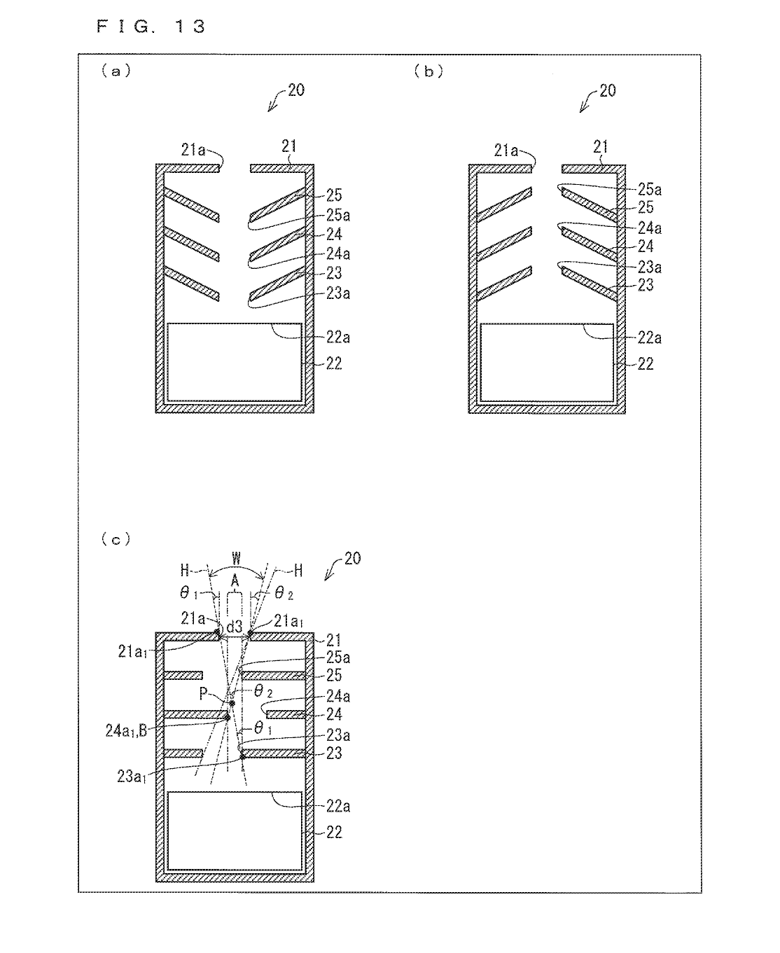

The present embodiment is described below mainly with reference to FIG. 12 and (a) through (c) of FIG. 13.

The present embodiment mainly describes differences from Embodiments 1 and 2. Note that members that have identical functions to those of Embodiments 1 and 2 are given identical reference numerals, and are not explained repeatedly.

<Configuration of Vapor Deposition Particle Injecting Devices 20 and 30>

FIG. 12 is a cross-sectional view schematically illustrating a configuration of a vapor deposition particle injecting device 20 in accordance with the present embodiment.

FIG. 12 also illustrates, as an example, the vapor deposition particle injecting device 20. Note, however, that the configuration of the vapor deposition particle injecting device 30 is of course equal to a configuration obtained by reading the reference numerals 20 through 26 as the respective reference numerals 30 through 36.

Also in FIG. 12, illustration of a heat exchanger 26 is omitted.

The vapor deposition particle injecting device 20 in accordance with the present embodiment is arranged such that through holes (an injection hole 21a and openings of at least two plate members) in a vapor deposition source have respective opening sizes which become smaller as a distance from an uppermost layer (i.e., a distance from the injection hole 21a) becomes shorter.

In the example illustrated in FIG. 12, the injection hole 21a and openings 23a through 25a of respective plate members 23 through 25 have sizes which become smaller as a distance from the injection hole 21a becomes shorter.

An angle formed by connecting the through holes (the openings 23a through 25a and the injection hole 21a) coincides with a desired injection angle of vapor deposition particles. In other words, the sizes of the openings 23a through 25a and the injection hole 21a are determined in accordance with the injection angle of the vapor deposition particles to be injected from the vapor deposition particle injecting device 20.

The configuration of the vapor deposition particle injecting device 20 in accordance with the present embodiment is identical to that described in Embodiment 1 except for the points described above.

From this, in the example illustrated in FIG. 12, a range W in which vapor deposition particles can be injected from a crucible 22 directly outside via the injection hole 21a (i.e., a range in which vapor deposition particles can be injected from a first space layer D, in which the crucible 22 is provided, in a holder 21 directly outside via the injection hole 21a) is obtained by extending outwards (i.e., toward each of the two opposite sides) an injection hole width d3 (opening size, diameter) of the injection hole 21a by the angle θ₁ (i.e., θ₀) from a normal direction with respect to each of the opening edges of the injection hole 21a.

In the present embodiment, however, d3 is smaller than that in the vapor deposition particle injecting device 20 illustrated in FIG. 1 (see FIG. 11). Also in the present embodiment, the range W in which vapor deposition particles are injected from the crucible 22 directly outside via the injection hole 21a can be arbitrarily set by changing the injection hole width d3 of the injection hole 21a and the angle θ₁ (θ₀).

In the vapor deposition particle injecting device 20 illustrated in FIG. 12, sizes (ranges) of R2 and R3 are likely to be smaller than those in the vapor deposition particle injecting devices 20 illustrated in FIGS. 1 and 11.

According to the present embodiment, it is therefore likely that an amount of vapor deposition particles injected from space layers to outside the injection hole 21a via the through holes become smaller than that in the vapor deposition particle injecting devices 20 illustrated in FIGS. 1 and 11.

On the other hand, however, vapor deposition particles trapped in the space layers, i.e., between adjacent plate members can easily return to a crucible 22. The vapor deposition particles which have returned to the crucible 22 are injected outside via the injection hole 21a directly from the crucible 22, and it is therefore possible to further improve directivity.

In the present embodiment, depending on design, there are cases where an opening of a plate member (e.g., the opening 24a of the plate member 24) located above the lowermost plate member 23 is larger than the opening 23a of the plate member 23, contrary to Embodiment 2.

As in Embodiment 2, this depends on location of an intersection P of (i) a line H (line H1) connecting an opening edge, on one of two opposite sides (on the left in FIG. 12) of the area A, of the opening 23a of the lowermost plate member 23 and an opening edge, on the other of the two opposite sides (on the right in FIG. 12), of the injection hole 21a and (ii) a line H (line H2) connecting opening edges that are opposite, via the region A, to the opening edges defining the line H1, i.e., an opening edge, on the other of the two opposite sides (on the right in FIG. 12), of the opening 23a of the lowermost plate member 23 and an opening edge, on the one of two opposite sides (on the left in FIG. 12), of the injection hole 21a.

Therefore, such cases are also assumed in which the through holes become larger first and then become smaller as a distance from an uppermost layer becomes shorter.

That is, in the present embodiment, out of the openings 23a through 25a of the respective plate members 23 through 25 and the injection hole 21a, the injection hole 21a and at least some of the openings 23a through 25a which overlap each other when viewed in a direction perpendicular to opening planes of the injection hole 21a and of the openings 23a through 25a have respective opening diameters which become smaller as a distance from the injection hole 21a becomes shorter.

In other words, openings of respective plate members and the injection hole 21a are formed so that the injection hole 21a and openings of at least two of the plate members have respective opening diameters which become smaller as a distance from the injection hole 21a becomes shorter.

<Manufacturing of Vapor Deposition Particle Injecting Devices 20 and 30>

The vapor deposition particle injecting devices 20 and 30 in accordance with the present embodiment can be designed and manufactured as described below. Note that the following description also takes, as an example, the vapor deposition particle injecting device 20.

First, first auxiliary lines (i.e., the lines K (K1 and K2) in FIG. 12) are drawn from the opening edges of the injection hole 21a so as to form an angle of θ₃.

Then, the plate member 25 is designed and disposed so that the opening edges of the opening 25a of the plate member 25 are located on the first auxiliary lines (i.e., the lines K1 and K2).

Next, second auxiliary lines (i.e., the lines I (I1 and I2) in FIG. 12) are drawn from the opening edges of the injection hole 21a so as to form an angle of θ₂ which is smaller than θ₃.

Then, the plate member 24 is designed and disposed so that the opening edges of the opening 24a of the plate member 24 are located on the first auxiliary lines (i.e., the lines I1 and I2). Here, the opening 24a of the plate member 24, which is a lower one of two plate members defining a third space layer F (i.e., an upper one of two plate members defining a second space layer E), is designed to have an opening width larger than that of the opening 25a of the plate member 25, which is an upper one of the two plate members defining the third space layer F.

By repeating the above procedure, such a structure can be formed in which through holes in a vapor deposition source become smaller as a distance from an uppermost layer becomes shorter. Note that the plate members 23 through 25 are designed and disposed so as to satisfy the formula (2).

<Modification Example>

(a) through (c) of FIG. 13 are cross-sectional views each illustrating a modification example of the vapor deposition particle injecting device 20.

As illustrated in (a) and (b) of FIG. 13, the plate members 23 through 25, which are perpendicular to a direction perpendicular (vertical) to a substrate surface of the film formation substrate 200 in FIGS. 1 through 3, 10 through 12, etc., can be inclined with respect to the substrate surface of the film formation substrate 200.

As illustrated in (c) of FIG. 13, center positions of the injection hole 21a and the openings 23a through 25a of the plate members 23 through 25 can be deviated from each other. Note, however, that the openings 23a through 25a and the injection hole 21a overlap each other at least in part (the region A) when viewed in a direction perpendicular to the substrate surface of the film formation substrate 200. In other words, there exists a range in which vapor deposition particles can be directly injected from the crucible 22.

The vapor deposition particle injecting devices 20 illustrated in (a) and (b) of FIG. 13 are identical in structure to the vapor deposition particle injecting device 20 illustrated in FIG. 1 except for that the plate members 23 through 25 are inclined with respect to a direction perpendicular to the substrate surface of the film formation substrate 200 (i.e., a direction perpendicular to opening planes of the openings 23a through 25a and the injection hole 21a).

Accordingly, in the examples illustrated in (a) and (b) of FIG. 13, the range W in which vapor deposition particles are injected from the crucible 22 directly outside via the injection hole 21a is identical to that in the vapor deposition particle injecting device 20 illustrated in FIG. 1.

However, in the example illustrated in (c) of FIG. 13, in the cross section illustrated in (c) of FIG. 13, a lower end (lower opening edge 23a₁) of an opening edge of the lowermost plate member 23 is a lower end of an opening edge of a lowermost plate member that is located on a line H connecting (i) the lower end (lower opening edge 23a₁) of the opening edge, on one (in this case, on the right in (c) of FIG. 13) of two opposite sides of the region A, of the lowermost plate member 23 and (ii) an upper end (upper opening edge 21a₁) of an opening edge, on the other one (in this case, on the left in (c) of FIG. 13) of the two opposite sides, of the injection hole 21a of the holder 21.

Meanwhile, in the cross section illustrated in (c) of FIG. 13, a lower end (lower opening edge 24a₁) of an opening edge of the plate member 24 is a lower end of an opening edge of a lowermost plate member that is located on a line H connecting (i) a lower end of an opening edge, on the other one (in this case, on the left in (c) of FIG. 13) of two opposite sides of the region A, of the lowermost plate member 23 and (ii) an upper end (upper opening edge 21a₁) of an opening edge, on the other one (in this case, on the right in (c) of FIG. 13) of the two opposite sides of the region A, of the injection hole 21a of the holder 21.

Accordingly, in the example illustrated in (c) of FIG. 13, the range W in which vapor deposition particles are injected from the crucible 22 directly outside via the injection hole 21a is obtained by extending outwards the injection hole width d3 of the injection hole 21a by θ₁ and θ₂ from a normal direction with respect to each of the opening edges of the injection hole 21a.

In a case where two vapor deposition sources are used so that vapor deposition is carried out in a region in which spread ranges of vapor deposition particles injected from the respective two vapor deposition sources overlap each other as illustrated in FIG. 2 and (a) of FIG. 4, it is therefore possible (i) to increase the region in which the spread ranges of vapor deposition particles injected from the respective two vapor deposition sources overlap each other and (ii) to reduce the other regions in which the spread ranges of vapor deposition particles injected from the respective two vapor deposition sources do not overlap each other, by making each of the spread ranges unbalanced as described above.

### Embodiment 4

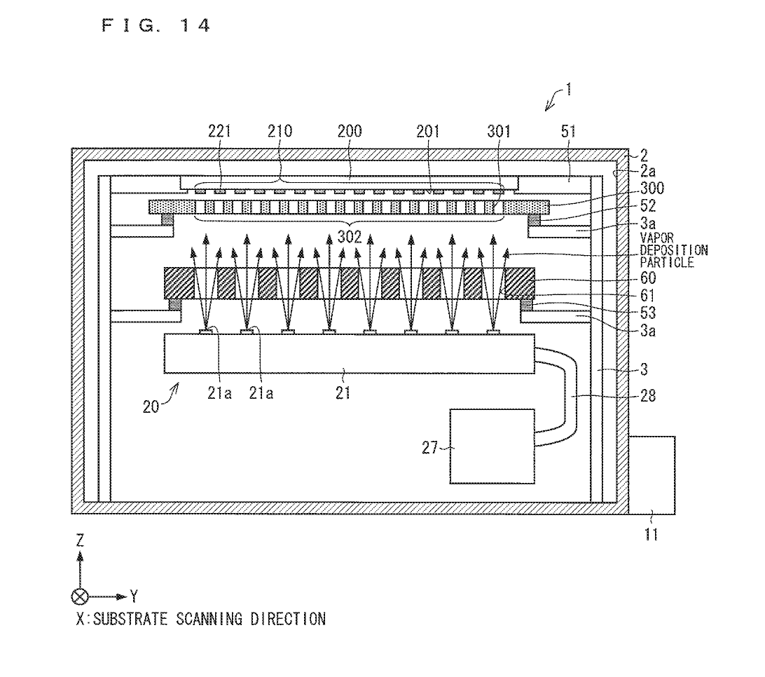

The present embodiment is described below mainly with reference to FIGS. 14 through 16.

The present embodiment mainly describes differences from Embodiments 1 through 3. Note that members that have identical functions to those of Embodiments 1 through 3 are given identical reference numerals, and are not explained repeatedly.

<Overall Configuration of Vapor Deposition Device 1>

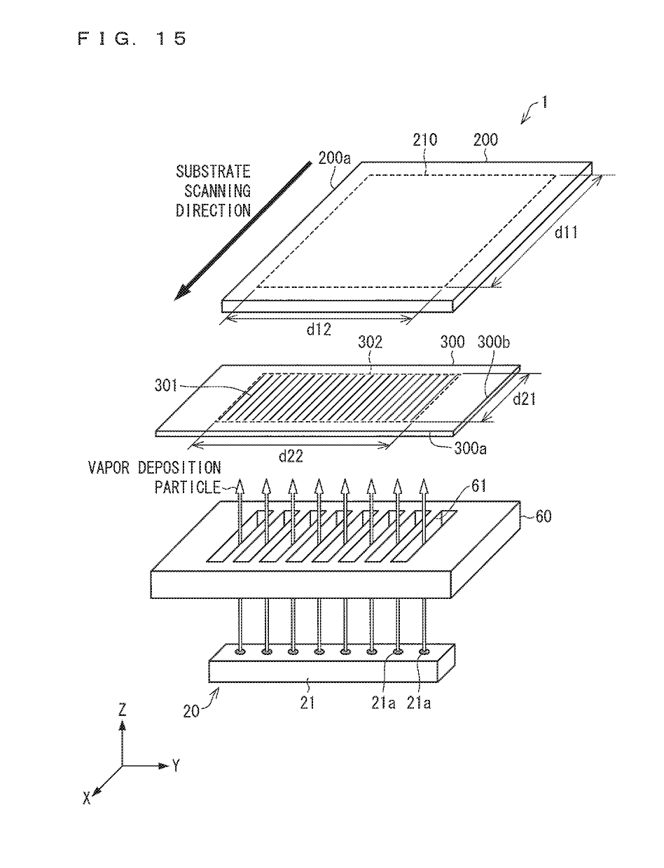

FIG. 14 is a cross-sectional view schematically illustrating a configuration of a main part of a vapor deposition device 1 in accordance with the present embodiment. FIG. 15 is a perspective view schematically illustrating main constituent elements in a vacuum chamber 2 of the vapor deposition device 1, in accordance with the present embodiment.

Embodiments 1 through 3 dealt with an example in which the vapor deposition mask 300 is fixed in close contact with the film formation substrate 200.

Differently from Embodiments 1 through 3, the present embodiment discusses an example in which a contactless mask is used as a vapor deposition mask 300 and scan vapor deposition is carried out while securing a certain gap between the mask 300 and a film formation substrate 200. Further, in the present embodiment, a vapor deposition particle injecting device 20 having a plurality of injection holes 21a is used as a vapor deposition source, and a restriction plate 60 is provided between the mask 300 and the vapor deposition particle injecting device 20.

As illustrated in FIG. 14, the vapor deposition device 1 in accordance with the present embodiment includes the vacuum chamber 2, a frame 3, a substrate moving unit 51, a mask supporting unit 52, a restriction plate supporting unit 53, a vapor deposition particle injecting device moving unit 7, the vapor deposition particle injecting device 20, the restriction plate 60, and a control section (not illustrated) (control circuit).

The frame 3, the substrate moving unit 51, the mask supporting unit 52, the restriction plate supporting unit 53, the vapor deposition particle injecting device moving unit 7, the vapor deposition particle injecting device 20, and the restriction plate 60 are provided inside the vacuum chamber 2. In the vacuum chamber 2, the vapor deposition mask 300 and the film formation substrate 200 are provided above the vapor deposition particle injecting device 20 so as to face the vapor deposition particle injecting device 20.

Note that a shutter 5 and a shutter operating unit 6 may be provided inside the vacuum chamber 2 although illustration of the shutter 5 and the shutter operating unit 6 is omitted in FIGS. 14 and 15.

Note that configurations of the shutter 5 and the shutter operating unit 6 are identical to those described above except for that the shutter 5 and the shutter operating unit 6 open/block an injection path of vapor deposition particles which are directed from the vapor deposition particle injecting device 20 toward the mask 300 instead of opening/blocking an injection path of vapor deposition particles which are directed from the vapor deposition particle injecting devices 20 and 30 toward the mask 300. Therefore, the shutter 5 and the shutter operating unit 6 are not explained repeatedly in the present embodiment.

The following discusses differences from Embodiment 1.

<Configuration of Mask 300>

The mask 300 used in the present embodiment has a size smaller than a film formation area 210 of the film formation substrate 200 (see FIG. 15).

Differently from Embodiments 1 through 3, according to the present embodiment, the mask 300 and the film formation substrate 200 are spaced away from each other by a certain gap in a Z-axis direction which is a direction perpendicular to a mask surface of the mask 300 (i.e., opening formation surface of the mask 300) as illustrated in FIGS. 14 and 15.

The mask 300 and the vapor deposition particle injecting device 20 are spaced away from each other by a certain gap in the Z-axis direction which is a direction perpendicular to the mask surface of the mask 300. Note that a relative position of the vapor deposition particle injecting device 20 and the mask 300 is fixed. Note, however, that the position of the mask 300 and the vapor deposition particle injecting device 20 is slightly movable (variable) for an alignment operation.

Also in the present embodiment, the mask 300 has a plurality of belt-like (striped) openings 301 (through holes) which are arranged in a one-dimensional direction (see FIGS. 14 and 15).

In the present embodiment, the openings 301 that extend in parallel with each other in a lateral direction (shorter side 300b) of the mask 300 are arranged in a longitudinal direction (longer side 300a) of the mask 300 (see FIG. 15).

In the present embodiment, scan vapor deposition is carried out while scanning the film formation substrate 200 in the lateral direction of the mask 300 (see FIG. 15).

That is, in the present embodiment, the longitudinal direction of the openings 301 is in parallel with a scanning direction (i.e., substrate carrying direction, an X-axis direction in FIGS. 14 and 15), and the plurality of openings 301 are arranged in a direction (i.e., a Y-axis direction in FIGS. 14 and 15) perpendicular to the scanning direction.

In the present embodiment, the mask 300 is formed so that a width d21 (equal to widths of the openings 301) of an opening area 302 of the mask 300 in a direction parallel to the scanning direction of the film formation substrate 200 is shorter than a width d11, in the direction parallel to the scanning direction, of a film formation area 210 (panel region) of the film formation surface 201 of the film formation substrate 200 (see FIG. 15).

Meanwhile, a width d22 of the opening area 302 of the mask 300 in the direction perpendicular to the scanning direction of the film formation substrate 200 is, for example, set in accordance with a width d12, in the direction perpendicular to the scanning direction, of the film formation area 210 (panel region) of the film formation substrate 200 so that film formation can be carried out, with a single scanning operation, all over the film formation area in the direction perpendicular to the scanning direction.

Note, however, that the present embodiment is not limited to this. For example, the width d22 may be smaller than the width d12. In this case, the mask supporting unit 52 and the frame 3 are redesigned in accordance with the size of the mask 300.

Note, also, that the size of the mask 300 with respect to the film formation substrate 200 can be arbitrarily set, and is not limited to a specific one.

The present embodiment discusses an example in which (i) the vapor deposition particle injecting device 20 and the mask 300 are fixed (but are moved as needed for alignment), and (ii) a vapor deposition material is deposited on the film formation substrate 200 through openings 301 of the mask 300 by carrying (in-line carriage) the film formation substrate 200 in the direction parallel to the longitudinal direction (longer side 200a) of the film formation substrate 200 above the mask 300.

Note, however, that the present embodiment is not limited to this. It is also possible to employ an arrangement in which the film formation substrate 200 is fixed and the vapor deposition particle injecting device 20 and the mask 300 are moved. Alternatively, it is also possible to employ an arrangement in which and at least one of (i) the vapor deposition particle injecting device 20 and the mask 300 and (ii) the film formation substrate 200 is moved with respect to the other.

A direction of the longer side 200a of the film formation substrate 200 with respect to the mask 300 is not limited to that described above. Needless to say, depending on a size of the film formation substrate 200, the mask 300 and the film formation substrate 200 may be disposed so that the longer side 200a of the film formation substrate 200 is parallel with the longer side 300a of the mask 300.

It is only necessary that the relative position of the vapor deposition particle injecting device 20 and the mask 300 be fixed. The vapor deposition particle injecting device 20 and the mask 300 may be provided so as to be integral with each other as a mask unit held by a common holding member or may be provided independently of each other.

In a case where the vapor deposition particle injecting device 20 and the mask 300 are moved with respect to the film formation substrate 200, the vapor deposition particle injecting device 20 and the mask 300 may be moved with respect to the film formation substrate 200 with the use of a common moving mechanism while being held by a common holding member as described above.

<Configuration of Frame 3>

As in Embodiment 1, the frame 3 is provided so as to be adjacent to an inner wall 2a of the vacuum chamber 2 (see FIG. 14). The frame 3 is used as a deposition preventing plate (shielding plate) and as a component supporting member in the vacuum chamber.

In the present embodiment, the substrate moving unit 51, the mask supporting unit 52, and the restriction plate supporting unit 53 are held by and fixed to the frame 3.

<Configurations of Substrate Moving Unit 51 and Mask Supporting Unit 52>

In the present embodiment, the mask 300 and the film formation substrate 200 are provided so as to be away from each other as described above. On this account, the substrate moving unit 51 and the mask supporting unit 52 are provided instead of the movable supporting unit 4.

The substrate moving unit 51 is a substrate moving unit which supports the film formation substrate 200 in a movable (carriable) manner while keeping a horizontal posture of the film formation substrate 200.

The mask supporting unit 52 supports the mask 300 in a fixed manner while keeping a horizontal posture of the mask 300.

The substrate moving unit 51 can have, for example, a similar configuration to the movable supporting unit 4.

That is, the substrate moving unit 51 includes (i) a driving section made up of a motor (XYθ driving motor) such as a stepping motor (pulse motor), a roller, a gear, and the like and (ii) a drive control section such as a motor drive control section. The drive control section drives the driving section so that the film formation substrate 200 is moved.

The substrate moving unit 51 moves the film formation substrate 200 such as a TFT substrate 110 while holding the film formation substrate 200 so that a film formation surface 201 faces the mask surface of the mask 300.

In the present embodiment, the mask 300 that is smaller in size than the film formation substrate 200 is used, and a vapor deposition material is deposited by carrying (in-line carriage) the film formation substrate 200 on a YX-plane in the X-axis direction above the mask 300 with the use of the substrate moving unit 51.

In the example illustrated in FIG. 14, the film formation substrate 200 is held by the substrate moving unit 51 from a bottom surface of the film formation substrate 200 (i.e., from a film formation surface 201 side). Note, however, that the present embodiment is not limited to this.

For example, the substrate moving unit 51 may include, as a substrate holding member, a fixing plate which is moved by a driving member such as a motor or a hydraulic pump.

By adhering the film formation substrate 200 to the fixing plate by suction with the use of an electrostatic chuck or the like so that the film formation substrate 200 is held from an entire non film formation surface (i.e., a surface opposite to the film formation surface 201) of the film formation substrate 200, it is possible to prevent the film formation substrate 200 from being bent due to its own weight even in a case where a large-sized substrate is used as the film formation substrate 200. This makes it possible to easily maintain a certain distance between the film formation substrate 200 and the mask 300.

<Vapor Deposition Particle Injecting Device 20>

As described above, two vapor deposition sources each having only one injection hole extending in a direction (the Y-axis direction) perpendicular to the substrate scanning direction are used in Embodiment 1.

That is, in a case where the mask 300 has the plurality of openings 301, two vapor deposition sources each having only one injection hole are provided in Embodiment 1 in a direction in which the openings 301 are arranged.

In this case, the range W in which vapor deposition particles are injected from the crucible 22 directly outside via the injection hole 21a can be easily and arbitrarily set by changing the injection hole width d3 of the injection hole 21a and the angle θ₁ (θ₀). It is therefore possible to easily set and control a vapor deposition range.

Meanwhile, a single vapor deposition source having a plurality of injection holes arranged in a direction perpendicular to the substrate scanning direction is used in the present embodiment.

That is, in the present embodiment, the vapor deposition particle injecting device 20 having the plurality of injection holes 21a arranged in the direction perpendicular to the substrate scanning direction is provided, as a vapor deposition source, in the vacuum chamber 2 (see FIGS. 14 and 15).

The injection holes 21a of the vapor deposition particle injecting device 20 are arranged in the direction perpendicular to the substrate scanning direction in accordance with lengthy structures of the mask 300 and the restriction plate 60 (see FIG. 15).

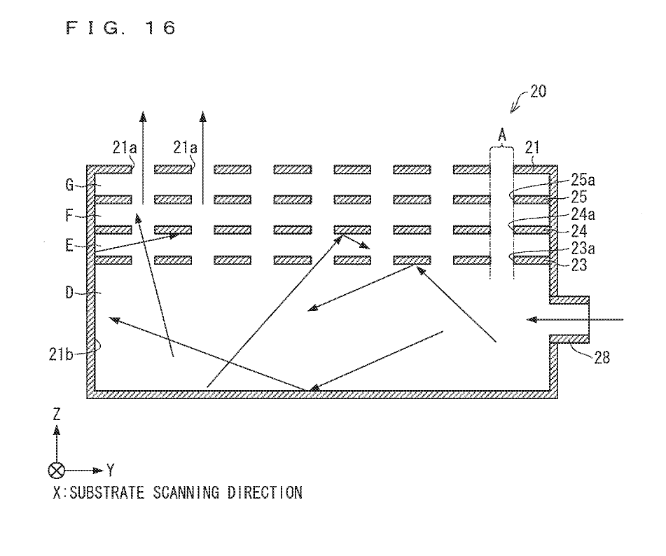

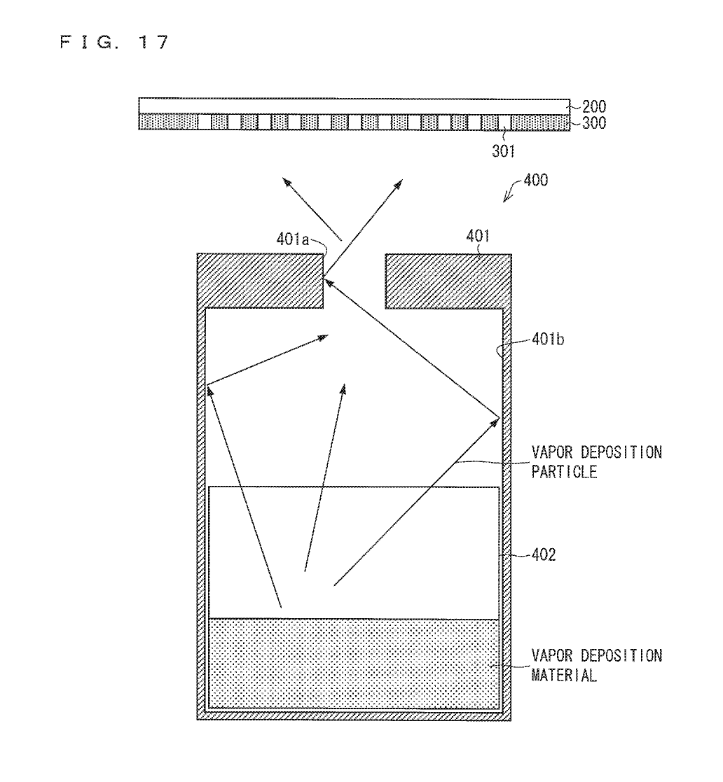

FIG. 16 is a cross-sectional view schematically illustrating a configuration of the vapor deposition particle injecting device 20 in accordance with the present embodiment.

As illustrated in FIGS. 14 and 16, the vapor deposition particle injecting device 20 in accordance with the present embodiment is arranged such that a container for vapor deposition material supply is provided outside the holder 21 as a vapor deposition material supplying section 27 which supplies gaseous vapor deposition particles into the holder 21, instead of providing a crucible 22 inside the holder 21 as a vapor deposition material generating section. The vapor deposition material supplying section 27 and the holder 21 are connected to each other via a pipe 28 for introducing the vapor deposition particles.

The vapor deposition material supplying section 27 and the pipe 28 may be provided inside the vapor deposition chamber 2 or may be provided outside the vapor deposition chamber 2. The pipe 28 can be, for example, a load-lock pipe.

The vapor deposition material supplying section 27 contains (stores) therein a solid or liquid vapor deposition material, as with the crucible 22. The vapor deposition material supplying section 27 is heated by a heat exchanger such as a heater (not illustrated).

This causes the vapor deposition material in the vapor deposition material supplying section 27 to evaporate (in a case where the vapor deposition material is a liquid material) or sublimate (in a case where the vapor deposition material is a solid material) into gas.

That is, in the present embodiment, the vapor deposition material supplying section 27 is used as a vapor deposition particle generating section for generating gaseous vapor deposition particles. Since the vapor deposition particle generating section is provided outside the holder 21 in the present embodiment, the holder 21 is used as a vapor deposition particle injection direction regulating section for regulating an injection direction of vapor deposition particles.

Also in the present embodiment, plate members 23 through 25 having respective openings 23a through 25a are stacked (overlap each other) in the holder 21 in the injection direction of vapor deposition particles, i.e., a direction perpendicular to opening planes of the openings 23a through 25a and the injection hole 21a so as to be away from each other, as in Embodiment 1.

Note that FIG. 16 illustrates a cross section taken along the direction in which the injection holes of the vapor deposition particle injecting device 20 are arranged (i.e., the direction perpendicular to the substrate scanning direction).

In the present embodiment, the injection holes 21a are formed in a top wall of the holder 21 and are arranged in a one-dimensional direction. Accordingly, a cross-sectional structure, in the substrate scanning direction, of the vapor deposition particle injecting device 20 in accordance with the present embodiment is identical to that of FIG. 1.

Also in the present embodiment, an inside of the holder 21 is divided into four space layers, i.e., a first space layer D, a second space layer E, a third space layer F, and a fourth space layer G by the plate members 23 through 25, and the openings 23a through 25a of the plate members 23 through 25 and the injection hole 21a overlap each other in a region A when viewed in a direction perpendicular to the opening planes of the openings 23a through 25a and the injection hole 21a (i.e., in a plan view), as in Embodiments 1 through 3.

A vapor deposition flow introduced (supplied) from the vapor deposition material supplying section 27 via the pipe 28 into a lowermost layer (the first space D), which serves as a vapor deposition particle introduction chamber in the holder 21, is injected to outside of the injection hole 21a via the openings 23a through 25a and the injection hole 21a.

The holder 21 has, on its both ends in the direction in which the injection holes are arranged (the direction perpendicular to the scanning direction), an inner wall surface (see FIG. 16), which exists in FIG. 1 on both ends of the holder 21 in the direction (the scanning direction) perpendicular to the direction in which the injection holes are arranged.

However, also in the cross section of FIG. 16 taken along the direction in which the injection holes are arranged, in a case where the openings 23a through 25a and the injection hole 21a are designed in a similar manner to that described in Embodiment 1 (for example, satisfy the equation (2)) as in the cross section of FIG. 1 taken along the direction perpendicular to the direction in which the injection holes are arranged, vapor deposition particles reflected and scattered by the inner wall 21b of the holder 21 are not directly injected outside via the injection hole 21a from the space layers other than the fourth space layer G which is an uppermost layer.

Therefore, the vapor deposition particle injecting device 20 in accordance with the present embodiment can produce a similar effect to that of the vapor deposition particle injecting device 20 in accordance with Embodiment 1.

In the present embodiment, only one injection hole 21a is provided in the substrate scanning direction as in FIG. 1. Note, however, that two or more injection holes 21a may be provided in the substrate scanning direction.

That is, the injection holes 21a may be two-dimensionally arranged. In this case, it is only necessary that a structure similar to that of FIG. 16 be formed also in the substrate scanning direction.

In FIG. 16, no inner wall surface is present between the injection holes 21a. However, an inner wall surface may be provided between the injection holes 21a by forming a wall between the injection holes 21a in order to equalize rigidity of the vapor deposition particle injecting device 20 and amounts of vapor deposition particles injected from the respective injection holes 21a. In this case, however, the equation (2) in Embodiment 1 need be satisfied.

In this case, the vapor deposition particle injecting device 20 can have, for example, a configuration equivalent to a plurality of vapor deposition particle injecting devices 20 each having the structure shown in FIG. 1 that are connected to each other.

Alternatively, the vapor deposition particle injecting device 20 can have a configuration equivalent to a plurality of vapor deposition particle injecting devices 20 each having the structure shown in FIG. 1 that are connected to each other by inner walls 21b of holders 21 in second space layers E through fourth space layers G but are continuous with each other in first space layers D with no inner wall 21b therebetween.

<Restriction Plate 60>

The restriction plate 60 has a plurality of openings 61 (through holes) penetrating in an up-and-down direction.

Vapor deposition particles injected to outside of the vapor deposition particle injecting device 20 from the injection holes 21a reach the film formation substrate 200 through the openings 61 of the restriction plate 60 and the openings 301 of the mask 300.

As illustrated in (a) of FIG. 4, vapor deposition particles injected from the injection hole 21a of the vapor deposition particle injecting device 20 radially spread to a certain degree.

However, an angle of vapor deposition particles injected from the injection holes 21a of the vapor deposition particle injecting device 20 towards the film formation substrate 200 is restricted to a certain angle or smaller by passing through the openings 61 of the restriction plate 60.

That is, in a case where scan vapor deposition is carried out with the use of the restriction plate 60, vapor deposition particles having an injection angle larger than a spread angle of vapor deposition particles restricted by the restriction plate 60 are all blocked by the restriction plate 60.

Therefore, an amount of a vapor deposition flow which passes through the openings 61 of the restriction plate 60 becomes larger and material utilization efficiency becomes higher as the spread angle of vapor deposition particles injected to the restriction plate 60 becomes smaller.

The vapor deposition particle injecting device 20 in accordance with the present embodiment is arranged such that the plurality of plate members 23 through 25 having the respective openings 23a through 25a are provided so as to constitute a plurality of stages in the holder 21 (see FIG. 16).

Accordingly, directivity of the vapor deposition flow is high as described above. Since this allows an increase in proportion of vapor deposition particles passing through the openings 61 of the restriction plate 60 as compared with the conventional art, the material utilization efficiency of the vapor deposition material is improved as compared with the conventional art. In addition, vapor deposition speed is improved as in Embodiment 1.

Since a vapor-deposited film 221 is formed on the film formation substrate 200 only from vapor deposition particles that have passed through the openings 61 of the restriction plate 60, it is possible to improve a film thickness distribution of a film formation pattern formed on the film formation substrate 200. This allows the vapor-deposited film 221 to be formed on the film formation substrate 200 with high accuracy without being blurred.

According to the present embodiment, centers of the openings 61 of the restriction plate 60, the injection holes 21a, and the openings 23a through 25a of the plate members 23 through 25 coincide with each other in a plan view. This makes it possible to suppress spread of the vapor deposition flow with high accuracy.

In the present embodiment, however, the injection holes 21a are different in size from the openings 61 of the restriction plate 60 (see FIGS. 14 and 15).

The size of the openings 61 of the restriction plate 60 can be appropriately set in accordance with a size of the film formation substrate 200 and a film formation pattern to be formed, and is not limited in particular. For example, the opening size of the openings 61 of the restriction plate 60 in a direction parallel to the scanning direction (the substrate carrying direction) is preferably 0.2 m or smaller.

Note, however, that even in a case where the opening size is larger than 0.2 m, there just occurs an increase in vapor deposition particle component which does not contribute to film formation due to an increase in amount of vapor deposition particles attached to the mask 300.

Meanwhile, in a case where the opening size of the openings 301 of the mask 300 in the direction parallel to the scanning direction (the substrate carrying direction) is too large, pattern accuracy declines.

Therefore, in order to secure accuracy with the current technological level, the opening size of the mask 300 need be 20 cm or smaller.

An opening size of the restriction plate 60 in the direction perpendicular to the scanning direction (the substrate carrying direction) is preferably 5 cm or smaller although it depends on the size of the film formation substrate 200 and a film formation pattern to be formed. In a case where the opening size is larger than 5 cm, there occur problems such as an increase in film thickness unevenness of the vapor-deposited film 221 on the film formation surface 201 of the film formation substrate 200 and an increase in disagreement between a pattern of the mask 300 and a pattern to be formed.

A location of the restriction plate 60 in the direction perpendicular to the film formation surface 201 of the film formation substrate 200 is not limited in particular, provided that the restriction plate 60 is provided between the mask 300 and the vapor deposition particle injecting device 20 so as to be away from the vapor deposition particle injecting device 20. The restriction plate 60 may be, for example, provided so as to be in close contact with the mask 300.

The restriction plate 60 is provided away from the vapor deposition particle injecting device 20 for the following reason.

The restriction plate 60 is not heated or is cooled by a heat exchanger (not illustrated) since the restriction plate 60 blocks an obliquely injected vapor deposition particle component. Accordingly, the restriction plate 60 has a lower temperature than the injection holes 21a of the vapor deposition particle injecting device 20.

Further, in a case where vapor deposition particles are not injected towards the film formation substrate 200, it is necessary to provide a shutter 5 (not illustrated) between the restriction plate 60 and the vapor deposition particle injecting device 20.

It is therefore necessary to secure a distance of at least 2 cm between the restriction plate 60 and the vapor deposition particle injecting device 20.

Note that a cooling mechanism for cooling the restriction plate 60 may be provided as needed as described above. This allows unnecessary vapor deposition particles that are not parallel to the normal direction to be cooled and solidified by the restriction plate 60, thereby allowing a direction in which vapor deposition particles travel to further approach the normal direction of the film formation substrate 200.

<Overview>

As above described, the vapor deposition particle injecting device of the embodiments includes: (1) a vapor deposition particle generating section for generating vapor deposition particles in a form of gas by heating up a vapor deposition material; (2) a holder having an injection hole through which the vapor deposition particles are injected outside, the number of the injection hole being at least one; and (3) a plurality of plate members provided so as to constitute respective of a plurality of stages in the holder, each of the plurality of plate members having a through hole whose number corresponds to the number of the injection hole, and the plurality of plate members being arranged between the vapor deposition particle generating section and the injection hole so as to be spaced from each other in a direction perpendicular to opening planes of the injection hole and of the through holes, and the injection hole and the through holes overlapping each other when viewed in the direction perpendicular to the opening planes of the injection hole and of the through holes.

According to the configuration, it is possible to increase a ratio of vapor deposition particles which are moved at a small injection angle towards the upper layer via the through holes. This allows an improvement in directivity.

Moreover, according to the configuration, it is possible to suppress or prevent collision and scattering of vapor deposition particles and to increase an apparent through hole length (nozzle length) in the opening direction of the injection hole. This allows an improvement in collimation (parallel flow) property of vapor deposition flows. As such, according to the configuration, it is possible to improve directivity of vapor deposition particles with a simple structure.

By employing the vapor deposition particle injecting device, distribution of a vapor deposition flow (vapor deposition particles) becomes smaller than that of a conventional technique, and it is therefore possible to improve material utilization efficiency. Further, the directivity is improved and the spread angle of vapor deposition particles can be made smaller, as compared with the conventional technique. Therefore, even in a case where a vapor deposition flow, which is identical in amount with that of the conventional technique, is injected, the density of vapor deposition particles becomes higher than that of the conventional technique, and accordingly a vapor deposition speed is improved.

It is preferable that center positions of the injection hole and of the through holes coinciding with each other when viewed in the direction perpendicular to the opening planes of the injection hole and of the through holes.

According to the configuration, the center positions of the injection hole and the through holes coincide with each other when viewed in the direction perpendicular to the opening planes of the injection hole and the through holes. With the configuration, the injection hole and the through holes are always to have an overlapping area.

This makes it possible to (i) bring about the above described effects and (ii) cause vapor deposition flows, which pass through the through holes, to become parallel flows. Further, it is possible to achieve a long apparent through hole length (nozzle length) in the opening direction of the through holes. This allows an improvement in collimation (parallel flow) property of the vapor deposition flows by the nozzle length effect.

According to the vapor deposition particle injecting device, it is preferable that, in a case where θ_{N} is a maximum angle between (i) an inner wall of the holder which inner wall is located between adjacent two of the plurality of plate members, the adjacent two of the plurality of plate members being a first plate member located on an injection hole side and a second plate member located on a vapor deposition particle generating section side and (ii) a line connecting (a) an end part of the inner wall which end part is located on the vapor deposition particle generating section side with (b) an opening edge of a first through hole of the first plate member, the opening edge being a part of the first through hole which part is located closest to the inner wall, and θ_{A} is a maximum angle between the opening edge and the injection hole when viewed in the direction perpendicular to the opening planes of the injection hole and of the through holes, a relation of θ_{N}>θ_{A} is satisfied.

According to the vapor deposition particle injecting device, it is preferable that an inner wall of the holder is located between adjacent two of the plurality of plate members, the adjacent two of the plurality of plate members being a first plate member located on an injection hole side and a second plate member located on a vapor deposition particle generating section side; and in a cross section of the holder taken along a center line of the injection hole, in a case where each of the first and second plate members is divided into two opposite sides by an area in which the injection hole and the through holes overlap each other when viewed in the direction perpendicular to the opening planes of the injection hole and of the through holes, the inner wall on one of the two opposite sides extends farther back from a second through hole of the second plate member than from a location at which a line, which connects (i) an opening edge of a first through hole of the first plate member, which opening edge is on the one of the two opposite sides, with (ii) an opening edge of the injection hole, which opening edge is on the other of the two opposite sides, intersects with the second plate member on the one of the two opposite sides.

According to the configurations, vapor deposition particles which have been reflected and scattered by the inner wall of the holder between adjacent plate members will not be directly injected. This reduces an amount of vapor deposition particles which are scattered from the inner wall surface of the holder and are then directly injected.

Consequently, a component ratio in the direction from the vapor deposition particle generating section to the film formation substrate is improved and a spread of vapor deposition particles is reduced. This allows an improvement in material utilization efficiency, and accordingly cost can be reduced in, for example, manufacturing the organic EL display device in which the vapor deposition particle injecting device is employed as the vapor deposition source.

According to the vapor deposition particle injecting device, it is preferable that the injection hole and at least some of the through holes have respective opening diameters which become larger as a distance from the injection hole becomes shorter. According to the configuration, it is possible (i) to allow a vapor deposition particle flow to be injected from the vapor deposition particle generating section directly to outside of the injection hole via the opening of the lowermost plate member (on the vapor deposition particle generating section side which is an upstream side in the vapor deposition particle injecting direction) without being hindered by plates (i.e., the plate members and the layer in which the injection hole of the holder is formed) which specify the openings in the plate members and the injection hole in upper stages, respectively (i.e., on the injection hole side which is a downstream side in the vapor deposition particle injecting direction), and (ii) to increase an amount of the vapor deposition particles injected via the through holes to outside of the injection hole.

This makes it possible to further improve vapor deposition speed.

In this case, it is preferable that the through holes and the injection hole are formed in accordance with an injection angle at which the vapor deposition particles are injected through the injection hole.

According to the vapor deposition particle injecting device, it is preferable that the injection hole and at least some of the through holes have respective opening diameters which become smaller as a distance from the injection hole becomes shorter.

According to the configuration, vapor deposition particles trapped between adjacent plate members can easily return to the vapor deposition particle generating section. The vapor deposition particles which have returned to the vapor deposition particle generating section are injected outside via the injection hole directly from the vapor deposition particle generating section, and it is therefore possible to further improve directivity.

It is preferable that the vapor deposition particle injecting device further includes an auxiliary plate which is provided between the vapor deposition particle generating section and the plurality of plate members, the auxiliary plate having a plurality of small holes whose diameter is smaller than those of the injection hole and of the through holes.

The auxiliary plate can be a mesh plate or a punched plate.

In a case where the auxiliary plate is provided between the vapor deposition particle generating section and the plurality of plate members, it is possible (i) to equalize density of vapor deposition particles emitted from different locations in the vapor deposition particle generating section and (ii) to prevent aggregated vapor deposition particles from being (a) emitted from the vapor deposition particle generating section and ultimately (b) injected via the injection hole as a cluster.

The vapor deposition device of the above described embodiments includes the vapor deposition particle injecting device as a vapor deposition source.

According to the vapor deposition device, therefore, it is possible to improve directivity of vapor deposition particles with a simple structure and to improve material utilization efficiency as above described.

Moreover, according to the configuration, the directivity is improved and the spread angle of vapor deposition particles can be made smaller, as compared with the conventional technique. Therefore, even in a case where a vapor deposition flow, which is identical in amount with that of the conventional technique, is injected, the density of vapor deposition particles becomes higher than that of the conventional technique, and accordingly a vapor deposition speed is improved.

It is preferable that a restriction plate for restricting passage of the vapor deposition particles is provided between the vapor deposition particle injecting device and a film formation substrate on which a film is to be formed.

Vapor deposition particles injected from the injection hole of the vapor deposition particle injecting device radially spread to a certain degree. However, an angle of vapor deposition particles injected towards the film formation substrate is restricted to a certain angle or smaller by passing through an opening of the restriction plate.

In this case, vapor deposition particles having an injection angle larger than a spread angle of vapor deposition particles restricted by the restriction plate are all blocked by the restriction plate. Therefore, an amount of a vapor deposition flow which passes through the opening of the restriction plate becomes larger and material utilization efficiency becomes higher as the spread angle of vapor deposition particles injected to the restriction plate becomes smaller.

As above described, the vapor deposition particle injecting device in accordance with the embodiments is arranged such that the plurality of plate members having the respective through holes are provided so as to constitute the plurality of stages in the holder.

Accordingly, directivity of the vapor deposition flow is high as described above. Since this allows an increase in proportion of vapor deposition particles passing through the opening of the restriction plate, the material utilization efficiency of the vapor deposition material is improved as compared with the conventional art. In addition, vapor deposition speed is also improved.

Since a vapor-deposited film is formed on the film formation substrate only from vapor deposition particles that have passed through the opening of the restriction plate, it is possible to improve a film thickness distribution of a film formation pattern formed on the film formation substrate. This allows the vapor-deposited film to be formed on the film formation substrate with high accuracy without being blurred.

It is preferable that the vapor deposition device includes a vapor deposition mask used to form a film pattern of a vapor-deposited film.

By using the vapor deposition mask, it is possible to obtain an intended film formation pattern.

The film pattern is an organic layer in an organic electroluminescence element. The vapor deposition device can be suitably employed as a device for manufacturing an organic electroluminescence element. That is, the vapor deposition device can be a device for manufacturing an organic electroluminescence element.

In a case where an organic electroluminescence element is carried out with the use of the vapor deposition particle injecting device of the embodiments, a method for manufacturing an organic electroluminescence element includes the steps of, for example, preparing a first electrode on a TFT substrate, vapor-depositing an organic layer, which includes at least a luminescent layer, on the TFT substrate, and vapor-depositing a second electrode, the vapor deposition particle injecting device being used as a vapor deposition source in at least one of the step of vapor-depositing an organic layer and the step of vapor-depositing a second electrode.

According to the configuration, therefore, it is possible to improve directivity of vapor deposition particles with a simple structure and to improve material utilization efficiency as above described. Moreover, as above described, the directivity is improved and the spread angle of vapor deposition particles can be made smaller, as compared with the conventional technique. Therefore, even in a case where a vapor deposition flow, which is identical in amount with that of the conventional technique, is injected, the density of vapor deposition particles becomes higher than that of the conventional technique, and accordingly a vapor deposition speed is improved.

According to the vapor deposition device, it is preferable that the vapor deposition mask has a plurality of openings; and the number of the injection hole of the vapor deposition particle injecting device is only one in a direction in which the plurality of openings of the vapor deposition mask are arranged.

In this case, a range (W) in which vapor deposition particles are directly injected outside from the vapor deposition particle generating section via the injection hole can be easily and arbitrarily set based on (1) an injection hole width (d3) of the injection hole and (2) (I) the normal line of an opening edge of a through hole in the plate member on one of two opposite sides of an area in which the injection hole and through holes overlap each other and (II) a maximum injection angle (θ₀) defined by an angle (θ₁) between the opening edge of the through hole and an opening edge of the injection hole on the other of the two opposite sides, when viewed in the direction perpendicular to the opening planes of the injection hole and the through holes. Therefore, it is possible to easily set and control the vapor deposition range.

The present invention is not limited to the embodiments, but can be altered by a skilled person in the art within the scope of the claims. An embodiment derived from a proper combination of technical means disclosed in respective different embodiments is also encompassed in the technical scope of the present invention.

### INDUSTRIAL APPLICABILITY

The vapor deposition particle injecting device and the vapor deposition device of the present invention can be suitably used in, for example, a device for and a method for manufacturing an organic EL display device, which are used in a film formation process such as a selective formation of organic layers in the organic EL display device.

### REFERENCE SIGNS LIST

1: Vapor deposition device
2: Vacuum chamber
2a: Inner wall
3: Frame
3a: Shelf
4: Movable supporting unit
5: Shutter
6: Shutter operating unit
7: Vapor deposition particle injecting device moving unit
8: Stage
9: Actuator
11: Vacuum pump
20: Vapor deposition particle injecting device
21: Holder
21a: Injection hole
21a₁: Upper opening edge
21b: Inner wall
22: Crucible (vapor deposition particle generating section)
23, 24, 25: Plate member
23a, 24a, 25a: Opening
23a₁, 24a₁, 25a₁: Lower opening edge
26: Heat exchanger
27: Vapor deposition material supplying section (vapor deposition particle generating section)
28: Pipe
30: Vapor deposition particle injecting device
31: Holder
31a: Injection hole
32: Crucible (vapor deposition particle generating section)
33, 34, 35: Plate member
40: Auxiliary plate
41: Small hole
51: Substrate moving unit
52: Mask supporting unit
53: Restriction plate supporting unit
60: Restriction plate
61: Opening
100: Organic EL display device
101R, 101G, 101B: Pixel
110: TFT substrate
111: Insulating substrate
112: TFT
113: Wire
114: Interlayer insulating film
114a: Contact hole
115: Edge cover
120: Organic EL element
121: First electrode
122: Hole injection layer/hole transfer layer
123R, 123G, 123B: Luminescent layer
124: Electron transfer layer
125: Electron injection layer
126: Second electrode
130: Adhesive layer
140: Sealing substrate
200: Film formation substrate
200a: Longer side
201: Film formation surface
210: Film formation area
221: Vapor-deposited film
300: Mask
300a: Longer side
301: Opening
302: Opening area
D: First space layer
E: Second space layer
F: Third space layer
G: Fourth space layer
M, N: Plate member
MA, NA: Opening
NA₁: Lower opening edge
P: Intersection

1-14. (canceled)

15. A method for forming a vapor-deposited film, comprising the steps of:
(i) causing at least one vapor deposition particle injecting device to face a film formation substrate via a vapor deposition mask having at least one opening, said at least one vapor deposition particle injecting device including
a vapor deposition particle generating section for generating vapor deposition particles in a form of gas by heating up a vapor deposition material,
a holder having an injection hole through which the vapor deposition particles are injected outside, the number of the injection hole being at least one,
a plurality of plate members provided so as to constitute respective of a plurality of stages in the holder, each of the plurality of plate members having a through hole whose number corresponds to the number of the injection hole, and the plurality of plate members being arranged between the vapor deposition particle generating section and the injection hole so as to be spaced from each other in a direction perpendicular to opening planes of the injection hole and of the through holes, and
an auxiliary plate which is provided between the vapor deposition particle generating section and the plurality of plate members, the auxiliary plate having a plurality of small holes whose diameter is smaller than those of the injection hole and of the through holes, and
the injection hole and the through holes overlapping each other when viewed in the direction perpendicular to the opening planes of the injection hole and of the through holes; and
(ii) evaporating or sublimating the vapor deposition material by heating the vapor deposition material, so that the vapor deposition material is injected as gaseous vapor deposition particles from said at least one vapor deposition particle injecting device and is vapor deposited on the film formation substrate via said at least one opening of the vapor deposition mask.

16. The method as set forth in claim 15, wherein said at least one vapor deposition particle injecting device includes a plurality of vapor deposition particle injecting devices, and the vapor deposition material is vapor deposited on the film formation substrate so as to be in an area in which spread ranges of the vapor deposition particles, which are injected from the plurality of vapor deposition particle injecting devices, overlap each other.

17. The method as set forth in claim 16, wherein
the vapor deposition mask is fixed in contact with the film formation substrate so that a film formation surface of the film formation substrate faces said at least one opening of the vapor deposition mask, and
the vapor deposition material is vapor deposited on the film formation substrate while the vapor deposition mask and the film formation substrate are carried above the plurality of vapor deposition particle injecting devices.

18. The method as set forth in claim 16, wherein
in each of the plurality of vapor deposition particle injecting devices, center positions of the injection hole and of the through holes are deviated from each other, and
the vapor deposition material is vapor deposited on the film formation substrate while each of the spread ranges of the vapor deposition particles injected from the plurality of vapor deposition particle injecting devices is unbalanced, so that the area in which the spread ranges of the vapor deposition particles overlap each other is increased and an area in which the spread ranges of the vapor deposition particles do not overlap each other is reduced as compared to a case where center positions of the injection hole and of the through holes coincide with each other.

19. The method as set forth in claim 15, wherein
the vapor deposition mask has a size smaller than that of the film formation substrate, and the vapor deposition material is vapor deposited on the film formation substrate while the vapor deposition mask and the film formation substrate are spaced away from each other by a certain gap therebetween and a relative position of said at least one vapor deposition particle injecting device and the vapor deposition mask is fixed and while at least one of (i) said at least one vapor deposition particle injecting device and the vapor deposition mask and (ii) the film formation substrate is moved with respect to the other.

20. The method as set forth in claim 19, further comprising a restriction plate having openings for restricting passage of the vapor deposition particles, the restriction plate being provided between the vapor deposition mask and each of the plurality of vapor deposition particle injecting devices, the vapor deposition material being vapor deposited on the film formation substrate through the openings of the restriction plate and said at least one opening of the vapor deposition mask.

21. The method as set forth in claim 15, wherein said at least one vapor deposition particle injecting device includes only one vapor deposition particle injecting device, and the vapor deposition material is vapor deposited on the film formation substrate while the film formation substrate is rotated.

22. The method as set forth in claim 15, wherein center positions of the injection hole and of the through holes coincide with each other when viewed in the direction perpendicular to the opening planes of the injection hole and of the through holes.

23. The method as set forth in claim 15, wherein
in a case where θ_{N} is a maximum angle between (i) an inner wall of the holder which inner wall is located between adjacent two of the plurality of plate members, the adjacent two of the plurality of plate members being a first plate member located on an injection hole side and a second plate member located on a vapor deposition particle generating section side and (ii) a line connecting (a) an end part of the inner wall which end part is located on the vapor deposition particle generating section side with (b) an opening edge of a first through hole of the first plate member, the opening edge being a part of the first through hole which part is located closest to the inner wall, and θ_{A} is a maximum angle between the opening edge and the injection hole when viewed in the direction perpendicular to the opening planes of the injection hole and of the through holes,
a relation of θ_{N}>θ_{A} is satisfied.

24. The method as set forth in claim 15, wherein:
an inner wall of the holder is located between adjacent two of the plurality of plate members, the adjacent two of the plurality of plate members being a first plate member located on an injection hole side and a second plate member located on a vapor deposition particle generating section side; and
in a cross section of the holder taken along a center line of the injection hole, in a case where each of the first and second plate members is divided into two opposite sides by an area in which the injection hole and the through holes overlap each other when viewed in the direction perpendicular to the opening planes of the injection hole and of the through holes, the inner wall on one of the two opposite sides extends farther back from a second through hole of the second plate member than from a location at which a line, which connects (i) an opening edge of a first through hole of the first plate member, which opening edge is on the one of the two opposite sides, with (ii) an opening edge of the injection hole, which opening edge is on the other of the two opposite sides, intersects with the second plate member on the one of the two opposite sides.

25. The method as set forth in claim 15, wherein:
among the injection hole and the through holes, the injection hole has a largest opening diameter and at least some of the through holes have respective opening diameters which become larger as a distance from the injection hole becomes shorter.

26. The method as set forth in claim 25, wherein:
the through holes and the injection hole are formed in accordance with an injection angle at which the vapor deposition particles are injected through the injection hole.

27. The method as set forth in claim 15, wherein:
among the injection hole and the through holes, the injection hole has a smallest opening diameter and at least some of the through holes have respective opening diameters which become smaller as a distance from the injection hole becomes shorter.

28. The method as set forth in claim 27, wherein center positions of the injection hole and of the through holes coincide with each other when viewed in the direction perpendicular to the opening planes of the injection hole and of the through holes.

29. The method as set forth in claim 27, wherein:
in a case where θ_{N} is a maximum angle between (i) an inner wall of the holder which inner wall is located between adjacent two of the plurality of plate members, the adjacent two of the plurality of plate members being a first plate member located on an injection hole side and a second plate member located on a vapor deposition particle generating section side and (ii) a line connecting (a) an end part of the inner wall which end part is located on the vapor deposition particle generating section side with (b) an opening edge of a first through hole of the first plate member, the opening edge being a part of the first through hole which part is located closest to the inner wall, and θ_{A} is a maximum angle between the opening edge and the injection hole when viewed in the direction perpendicular to the opening planes of the injection hole and of the through holes,
a relation of θ_{N}>θ_{A} is satisfied.

30. The method as set forth in claim 15, wherein the auxiliary plate is a mesh plate or a punched plate.

31. The method as set forth in claim 15, further comprising a restriction plate having openings for restricting passage of the vapor deposition particles, the restriction plate being provided between the vapor deposition mask and said at least one vapor deposition particle injecting device,
the vapor deposition material being vapor deposited on the film formation substrate through the openings of the restriction plate and said at least one opening of the vapor deposition mask.

32. The method as set forth in claim 15, wherein:
said at least one opening of the vapor deposition mask includes a plurality of openings; and
the number of the injection hole of said at least one vapor deposition particle injecting device is only one in a direction in which the plurality of openings of the vapor deposition mask are arranged.

33. A method for manufacturing an organic EL display device, comprising the method as set forth in claim 15.

34. The method as set forth in claim 33, wherein an organic layer in an organic EL display element of the organic EL display device is formed by the method as set forth in claim 15.
